(19) United States
(12) Patent Application Publication
(10) Pub. No.: US 2008/0180023 A1
(43) Pub. Date: Jul. 31, 2008

(54) Organic electroluminescence element

(75) Inventors: Manabu Tobise, Kanagawa (JP); Masaru Kinoshita, Kanagawa (JP)

Correspondence Address: BIRCH STEWART KOLASCH & BIRCH, PO BOX 747, FALLS CHURCH, VA, 22040-0747, US

(73) Assignee: FUJIFILM Corporation

(21) Appl. No.: 11/902,898

(22) Filed: Sep. 26, 2007

(30) Foreign Application Priority Data
Sep. 28, 2006 (JP) 2006-264841

(51) Int. Cl. H01J 1/63

(52) U.S. Cl. 313/504

(57) ABSTRACT

An organic electroluminescence element having at least a light-emitting layer between a pair of electrodes, wherein the light-emitting layer is divided into at least 3 unit light emitting layers in the thickness direction thereof, and at least 2 intermediate layers containing an electron-blocking material between the divided light emitting layers, wherein an electron-blocking capacity of the intermediate layer is highest in the intermediate layer disposed closer to the anode, and lowest in the intermediate layer disposed closer to the cathode. An organic EL element having high external quantum efficiency and driving durability is provided.

### CROSS-REFERENCE TO RELATED APPLICATION

This application claims priority under 35 USC 119 from Japanese Patent Application No. 2006-264841, the disclosure of which is incorporated by reference herein.

### BACKGROUND OF THE INVENTION

1. Field of the Invention

The present invention relates to an organic light emitting element which has improved external quantum efficiency, and in particular, to an organic light emitting element which can be effectively applied to a surface light source for a full color display, a backlight, an illumination light source or the like; or a light source array for a printer or the like.

2. Description of the Related Art

An organic light emitting element (hereinafter, referred to as an “organic EL element” in some cases) is composed of a light emitting layer or a plurality of functional layers containing a light emitting layer, and a pair of electrodes sandwiching these layers. The organic EL element is a device for obtaining luminescence by utilizing at least either one of luminescence from excitons each of which is obtained by recombining an electron injected from a cathode with a hole injected from an anode to produce the excitons, or luminescence from excitons of other molecules produced by energy transmission from the above-described excitons.

Heretofore, an organic EL element has been developed by using a laminate structure from integrated layers in which each layer is functionally differentiated, whereby brightness and device efficiency are remarkably improved. For example, it is described in “Science”, vol. 267, No. 3, page 1332, (1995) that a two-layer laminated type device obtained by laminating a hole transport layer and a light emitting layer also functioning as an electron transport layer; a three-layer laminated type device obtained by laminating a hole transport layer, a light emitting layer, and an electron transport layer; and a four-layer laminated type device obtained by laminating a hole transport layer, a light emitting layer, a hole blocking layer, and an electron transport layer have been frequently used.

However, many problems still remain for putting organic EL elements to practical use. First, there is a need to attain a high external quantum efficiency, and second, there is a need to attain a high driving durability.

For example, there has been disclosed in JP-A No. 2003-123984 an attempt to dispose an interface layer of 0.1 nm to 5 nm as a barrier layer between a light emitting layer and a hole transport layer and retard the migration of holes, to thereby control the migration balance between holes and electrons and enhance the external quantum efficiency. However, this means potentially involves a problem of lowering the brightness and increasing the driving voltage since the migration of all of the carriers is lowered, as well as a problem of lowering the driving durability, since the time that the carriers stay in the device is made longer.

Further, a configuration in which light emitting units each containing a light-emitting layer and a functional layer are stacked in a multi-layer structure is known. For example, JP-A No. 6-310275 discloses a configuration in which plural light emitting units including an organic electroluminescence element are isolated by an insulation layer, and opposing electrodes are provided for each of the light emitting units. However, in this configuration, since the insulation layer and the electrode between the light emitting units hinder the taking out of light emission, light emitted from each of the light emitting units cannot substantially be utilized sufficiently. Further, this is not a means for improving the low external quantum efficiency inherent to each of the light emitting units.

JP-A No. 2003-45676 discloses a multi-photon type organic EL element, in which a plurality of light-emitting layers are isolated from each other by an electrically insulating charge generation layer. However, in this configuration as well, the light emitting units are merely stacked in a plurality, and this cannot provide a means for improving the low external quantum efficiency inherent to each of the light emitting units.

Compatibility between high external quantum efficiency and high driving durability is extremely important for designing a light emitting element which is practically useful, and this is a subject for which improvement is continuously demanded.

### SUMMARY OF THE INVENTION

The present invention has been made in view of the above circumstances and provides an organic electroluminescence element having at least a light emitting layer between a pair of electrodes, wherein the light emitting layer is segmented into at least 3 unit light emitting layers in the thickness direction thereof, and at least 2 intermediate layers each containing an electron blocking material are disposed between the adjacent unit light emitting layers, wherein an electron blocking capacity of the intermediate layer is highest in the intermediate layer disposed closer to the anode, and lowest in the intermediate layer disposed closer to the cathode.

A second aspect of the present invention is to provide an organic electroluminescence element having at least a light emitting layer between a pair of electrodes, wherein the light emitting layer is segmented into at least 3 unit light emitting layers in the thickness direction thereof, and at least 2 intermediate layers each containing a hole blocking material are disposed between the adjacent unit light emitting layers, wherein a hole blocking capacity of the intermediate layer is lowest in the intermediate layer disposed closer to the anode, and highest in the intermediate layer disposed closer to the cathode.

### BRIEF DESCRIPTION OF THE DRAWINGS

FIG. 1 is a conceptual view of the layer configuration of a comparative light emitting element.

FIG. 2 is a conceptual view of the layer configuration of another comparative light emitting element, wherein a light emitting layer is segmented into 3 unit light emitting layers, and same intermediate layers are respectively disposed between the adjacent unit light emitting layers.

FIG. 3 is a conceptual view of one example of a light emitting element according to the present invention, wherein a light emitting layer is segmented into 3 unit light emitting layers, and 2 intermediate layers of different charge-blocking capacities are respectively disposed between the adjacent unit light emitting layers.

FIG. 4 is a conceptual view of a layer configuration of another example of the light emitting element according to the present invention, wherein a light emitting layer is segmented into 4 unit light emitting layers, and 3 intermediate layers having different charge-blocking capacities from each other are disposed between the adjacent unit light emitting layers.

FIG. 5 is a conceptual view of a layer configuration of still another example of the light emitting element according to the present invention, wherein the light emitting layer is segmented into 4 unit light emitting layers, and 3 intermediate layers having different thicknesses are respectively disposed between the adjacent unit light emitting layers.

### DETAILED DESCRIPTION OF THE INVENTION

An object of the present invention is to provide an organic electroluminescence element having improved external quantum efficiency.

The organic electroluminescence element according to the present invention has at least a light emitting layer between a pair of electrodes, wherein the light emitting layer is segmented into at least 3 unit light emitting layers in the thickness direction thereof, and at least 2 intermediate layers each containing an electron blocking material are disposed between the adjacent unit light emitting layers, wherein an electron blocking capacity of the intermediate layer is highest in the intermediate layer disposed closer to the anode, and lowest in the intermediate layer disposed closer to the cathode.

The electron blocking capacity of the intermediate layer can be preferably controlled by using electron blocking materials or hole blocking materials of different Ea values. The electron blocking capacity of the intermediate layer can be also controlled by varying concentration of an electron blocking material. Furthermore, the electron blocking capacity of the intermediate layer can be also controlled by varying thickness of the layers. Preferably, the intermediate layer disposed closer to the anode has the lowest electron mobility, and the intermediate layer disposed closer to the cathode has the highest electron mobility.

In another embodiment of the organic electroluminescence element according to the present invention, the intermediate layers each contain a hole blocking material, wherein a hole blocking capacity is lowest in the intermediate layer disposed closer to the anode, and highest in the intermediate layer disposed closer to the cathode.

The hole blocking capacity of the intermediate layer can be preferably controlled by using electron blocking materials or hole blocking materials of different Ip values. The hole blocking capacity of the intermediate layer can be also controlled by varying concentration of a hole blocking material. Furthermore, the hole blocking capacity of the intermediate layer can be also controlled by varying thickness of the layers. It is preferable that the intermediate layer disposed closer to the anode has the highest hole mobility, and the intermediate layer disposed closer to the cathode has the lowest hole mobility.

In other words, the organic electroluminescence element of the present invention has a multilayer integrated structure with a light emitting layer segmented into at least 3 thin unit light emitting layers in the thickness direction, and with at least 2 intermediate layers having different electron or hole blocking capacities disposed between the adjacent unit light emitting layers.

In a case where the organic electroluminescence element of the present invention has 3 or more intermediate layers, it can work as intended when an arbitrarily selected 3 layers satisfy the above requirement. For example, in the case of an organic electroluminescence element with intermediate layers containing an electron blocking material, wherein an electron blocking capacity of the intermediate layer closer to the anode is largest, and an electron blocking capacity of the intermediate layer closer to the cathode is smallest, the invention can work as intended if the intermediate layers disposed between these intermediate layers have an electron blocking capacity intermediate to those of these intermediate layers.

Preferably, the plurality of intermediate layers between the intermediate layer closest to the anode and the intermediate layer closest to the cathode have a greater electron-blocking capacity in the intermediate light-emitting layer closer to the anode than that closer to cathode.

As a result of analysis of causes why the external quantum efficiency in a light emitting element is low, it has been inferred that a primary emission occurs in the neighborhood of a very limited interface of a light emitting layer and an adjacent layer, and that charges, being localized in a very limited interface, gradually deteriorate before the recombination occurs.

As a result of earnest investigation for improvement, the present inventors have found that improvement can be achieved by segmenting a light emitting layer into a plurality of thin unit light emitting layers in the thickness direction, and disposing intermediate layers having charge-blocking capacity between the respective adjacent unit light emitting layers, wherein when the intermediate layer has an electron blocking capacity, the electron blocking capacity is highest in the intermediate layer closer to the anode and lowest in the intermediate layer closer to the cathode, and when the intermediate layer has a hole blocking capacity, the hole blocking capacity is lowest in the intermediate layer closer to the anode and highest in the intermediate layer closer to the cathode. In other words, the above structure reduces a distance between areas in which electrons are localized and areas in which holes are localized to accelerate their recombination speed, and also reduces leakage of carriers from each unit light emitting layer to improve luminescence efficiency. Moreover, as it is the intermediate layer that connects thin unit light emitting layers, there is no increase of driving resistance, and light produced in each of the thin unit light emitting layers can be emitted efficiently to the outside.

It is also preferable for the intermediate layer to contain a light emitting material to produce luminescence, whereby still brighter luminescence can be obtained.

Preferably, a light emitting material contained in the light emitting layer is a phosphorescent material. More preferably, a light emitting material contained in the intermediate layer is a phosphorescent material.

### 1. Segmentation of Light Emitting Layer

The organic EL element of the invention has at least a light emitting layer interposed between a pair of electrodes in which the light emitting layer is divided along the thickness direction thereof and an intermediate layer is disposed between the divided light emitting layers. The intermediate layer functions as an electric-charge blocking layer. In the present application, the finely divided light emitting layers, into which the light emitting layer is divided in the thickness direction thereof, are sometimes referred to as “unit light emitting layers”.

The thickness of the unit light emitting layer in the invention is preferably 2 nm to 50 nm, more preferably 2 nm to 40 nm, and further preferably 2 nm to 30 nm.

The light emitting layer in the invention is finely divided along the thickness direction thereof preferably into 3 layers to 50 layers, and more preferably into 4 layers to 30 layers.

The unit light emitting layers in the invention are connected by an intermediate layer. Preferably, the device comprises at least four unit light emitting layers and three intermediate layers connecting them along the thickness direction thereof.

The intermediate layer in the invention preferably contains a light emitting material. The intermediate layer in the invention preferably contains a hole blocking material or an electron blocking material as the charge blocking material.

Preferably, the intermediate layer contains a phosphorescence material as the light emitting material.

### (Intermediate Layer)

The intermediate layer in the invention will be described in more detail.

The intermediate layer in the invention functions as a charge blocking layer.

The intermediate layer which operates as a charge blocking layer in the invention is a layer having a function of suppressing electrons transported from a cathode to a light emitting layer from passing through to an anode, or suppressing holes transported from an anode to the light emitting layer from passing through to the cathode, but this is not a layer for completely inhibiting the migration of carriers.

Preferably, the intermediate layer contains a light emitting material. More preferably, the intermediate layer contains a phosphorescence material as the light emitting material.

1) Electron Blocking Material in the Intermediate Layer

An electron blocking material in the intermediate layer in the present invention is a material having an Ea value thereof in a range of 1.5 eV to 3.0 eV, and preferably in a range of 2.0 eV to 2.8 eV. An electron blocking material in the intermediate layer in the present invention preferably has a minimum Ea value in the intermediate layer closer to an anode, and has a maximum Ea value in the intermediate layer closer to a cathode.

The electron blocking capacity of the electron blocking material in the present invention depends on an Ea value, wherein the smaller the Ea value is, the larger the blocking capacity is. Furthermore, the higher the concentration of the electron blocking material in the electron blocking layer is, the thicker the thickness of the electron blocking layer is, or the smaller the electron mobility in the electron blocking layer is, the larger the electron blocking capacity is.

Specific examples of electron blocking materials satisfying these conditions preferably include hole transporting materials such as carbazole derivatives such as N,N′-di-carbazolyl-3,5-benzene (hereinafter, referred to as “mCP” in some cases) and N,N′-di-carbazolyl-4,4′-biphenyl (hereinafter, referred to as “CBP” in some cases), azacarbazole derivatives, indole derivatives, azaindole derivatives, pyrene derivatives, pyrrole derivatives, triazole derivatives or oxazole derivatives. Particularly preferably, hole transporting materials such as carbazole derivatives such as mCP and CBP or pyrene derivatives can be cited. However, as far as it is a material that can control so that electrons can appropriately enter into a light emitting layer, there is no particular restriction.

As specific compounds of the electron blocking materials, for instance, hole transporting materials such as shown below can be cited, but the invention is not limited thereto.

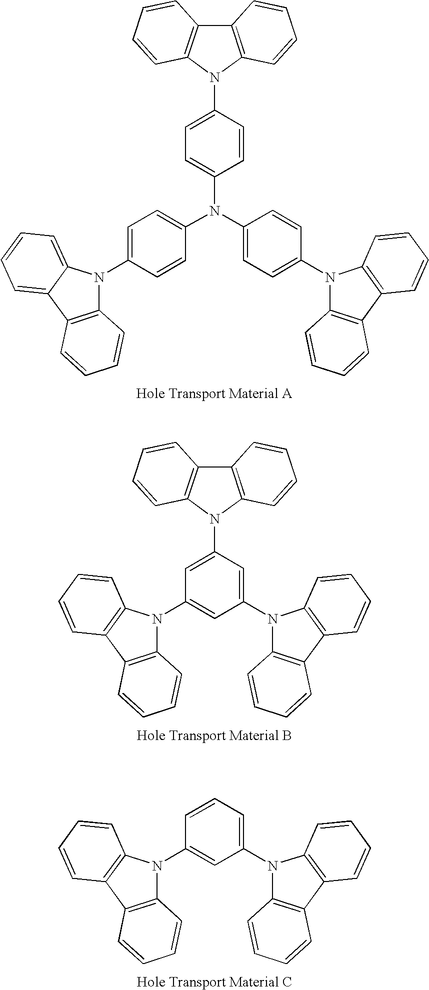

2) Hole Blocking Material in the Intermediate Layer

A hole blocking material in the intermediate layer in the present invention is a material having a Ip value thereof in a range of 5.0 eV to 8.0 eV, and preferably in a range of 5.5 eV to 7.0 eV. An hole blocking material in the intermediate layer in the present invention preferably has a minimum Ip value in the intermediate layer closer to an anode, and has a maximum Ip value in the intermediate layer closer to a cathode.

The hole blocking capacity of the hole blocking material in the present invention depends on an Ip value, wherein the larger the Ip value is, the larger the hole blocking capacity is. Furthermore, the higher the concentration of the hole blocking material in the hole blocking layer is, the thicker the thickness of the hole blocking layer is, or the smaller the hole mobility in the hole blocking layer is, the larger the hole blocking capacity is.

Specific examples of the hole blocking materials satisfying these conditions preferably include electron transporting materials such as aluminum complexes such as aluminium (III) bis-(2-methyl-8-quinolinato)-4-pnenylphenolate (hereinafter, referred to as “BAlq” in some cases), triazole derivatives, phenanthroline derivatives such as 2,9-dimethyl-4,7-diphenyl-1,10-phenanthroline (hereinafter, referred to as “BCP” in some cases), and imidazopyridine derivatives. Particularly preferable examples include electron transporting materials such as imidazopyridine derivatives. However, as far as it is a material that can control so that holes can appropriately enter into a light-emitting layer, there is no particular restriction.

As specific compounds of the hole blocking materials, for instance, electron transporting materials such as shown below can be cited, but the invention is not limited thereto.

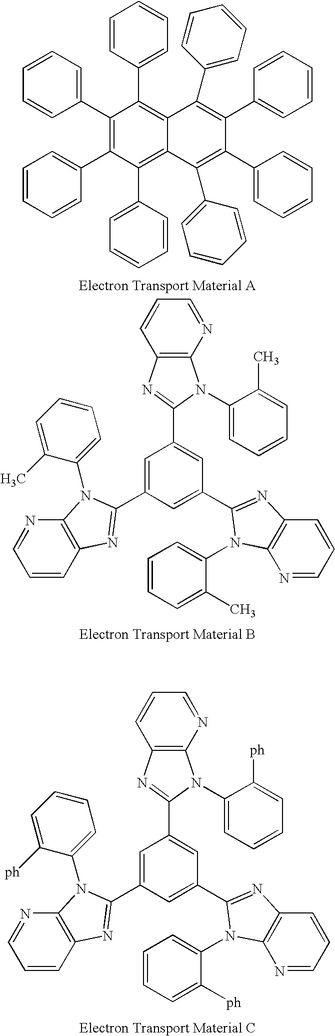

3) Constitution of Intermediate Layer

In general, the constituent ratio of the intermediate layer in the present invention preferably comprises from 5% by volume to 90% by volume of the charge blocking material, from 0% by volume to 30% by volume of the light emitting material, and from 0% by volume to 95% by volume of the charge transport material (total for the light emitting material and the charge transport material: 10% by volume to 95% by volume), further preferably, from 10% by volume to 80% by volume of the charge blocking material, 0% by volume to 30% by volume of the light emitting material, and 0% by volume to 90% by volume of the charge transport material (total for the light emitting material and the charge transport material: 20% by volume to 80% by volume), and even further preferably, from 30% by volume to 70% by volume of the charge blocking material, from 0% by volume to 30% by volume of the light emitting material, and from 0% by volume to 70% by volume of the charge transport material (total for the light emitting material and the charge transport material: 30% by volume to 70% by volume).

In a case where the charge blocking material exceeds 90% by volume, mobility of carriers is hindered greatly to increase the driving voltage, which is not preferred. In a case where the charge blocking material is less than 5% by volume, since the charge blocking performance is scarcely exhibited, this results in a problem in that the effect of improving the external quantum efficiency is not obtained, which is not preferred.

4) Thickness

For preventing an increase in driving voltage, in general, the thickness of the intermediate layer in the invention is preferably from 3 nm to 100 nm, and more preferably from 5 nm to 50 nm.

In a case where the thickness exceeds 100 nm, mobility of carriers is hindered greatly to result in a problem of increasing the driving voltage, which is not preferred. In a case where the thickness is less than 3 nm, the layer is not formed sufficiently and partially or entirely loses the function as the charge blocking layer, which is not preferred.

5) Number of Layers

The number of layers of the intermediate layer in the invention is preferably from 2 to 49, more preferably from 3 to 29, and further preferably from 4 to 14.

### (Segmentation of Light Emitting Layer)

Segmentation of the light emitting layer for the present invention is described. Composition of each light emitting layer is described later in detail in the description of the light emitting layer.

In the configuration according to the present invention, the light emitting layer is divided into 3 or more unit light emitting layers in the thickness direction. The number of the unit light emitting layers is preferably 4 to 30, and more preferably 5 to 15. Thicknesses of the unit light emitting layers decrease in a direction from the cathode toward the anode, when the intermediate layer contains an electron blocking material. On the other hand, thicknesses of the unit light emitting layers decrease in a direction from the anode toward the cathode, when the intermediate layer contains a hole blocking material.

The unit light emitting layer for the present invention is very thin, its thickness being 2 to 50 nm, preferably 2 to 40 nm, and more preferably 2 to 30 nm.

If the unit light emitting layer is thinner than 2 mm, sufficient luminescence cannot be obtained, and if the layer is thicker than 50 nm, the effects of the segmentation cannot be sufficiently obtained.

A plurality of light emitting layers in the invention may be layers exhibiting light emission identical with each other or exhibiting light emission different from each other with respect to wavelengths of the emitted light. For example, in a case of layers exhibiting light emission having identical wavelengths, light emission at high brightness can be taken out. On the other hand, in a case of light emission having different wavelengths from each other, it is possible to obtain light emission of a desired tone, or to obtain white light emission, depending on the combination of respective light emission wavelengths.

### (Configuration of Segmented Layers)

The layer constitution is to be described by referring to the attached drawings. These drawings of FIGS. 1 to 5 show only the layers necessary for describing the invention of the present invention, and description of elements not directly necessary for explaining the present invention is omitted, regardless whether or not they are essential for the light emitting element.

FIG. 1 is a conceptual view of a layer constitution of a comparative light emitting element. It comprises a substrate (not shown) which supports an anode 1 comprising ITO or the like, and a hole injection layer 2, a hole transport layer 3, a light emitting layer 4, an electron transport layer 5, an electron injection layer 6 and a cathode 7 comprising a metal such as aluminum, are disposed on the anode 1 in this order.

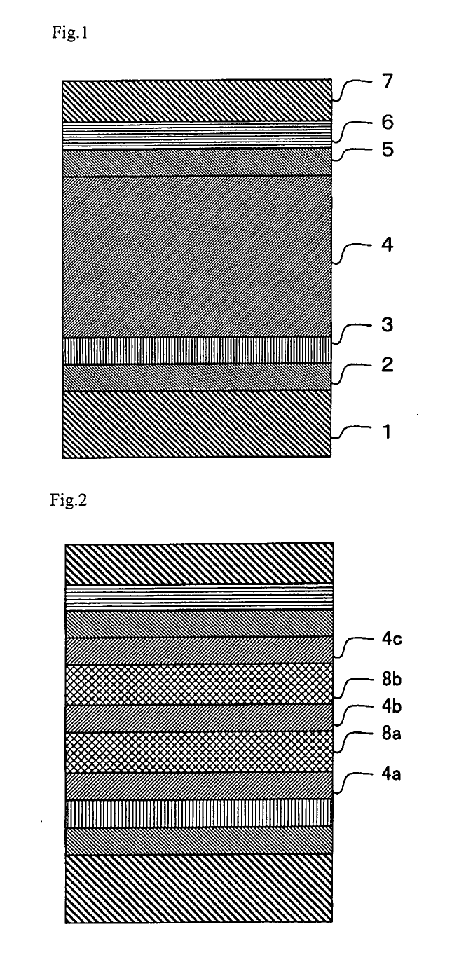

FIG. 2 is a schematic view of the layer constitution of another comparative light emitting element in which a light-emitting layer is divided into three light-emitting layers of a first unit light-emitting layer 4a, a second unit light-emitting layer 4b and a third unit light-emitting layer 4c, and intermediate layers 8a and 8b are disposed therebetween. The total thickness including the three divided light-emitting layers and two intermediate layers in FIG. 2 is substantially identical with that for the light-emitting layer 4 in FIG. 1.

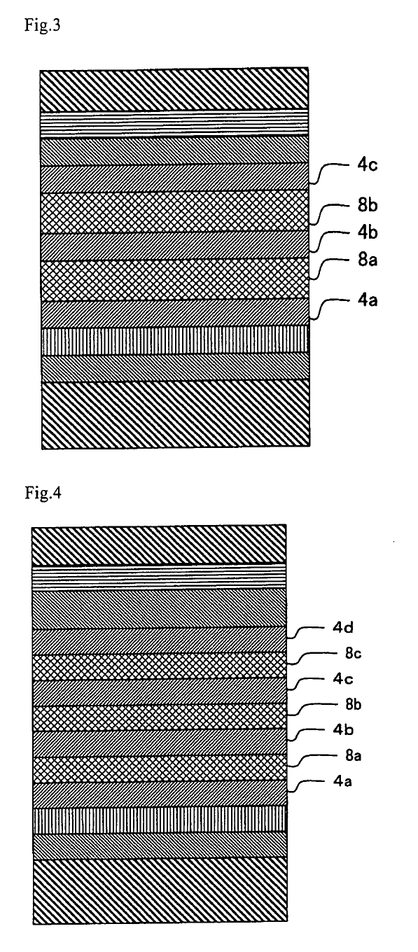

FIG. 3 is a conceptual view of one example of the light emitting element of the present invention, wherein the light emitting layer is segmented into 3 unit light emitting layers 4a, 4b and 4c, with 2 intermediate layers 8a and 8b being respectively disposed between the adjacent unit light emitting layers. The intermediate layer 8a contains an electron blocking material having a higher electron blocking capacity than that of an electron blocking material contained in the intermediate layer 8b. The total thickness of the 3 unit light emitting layers and 2 intermediate layers in FIG. 3 is substantially the same as that of the light emitting layer 4 shown in FIG. 1.

FIG. 4 is a conceptual view of a layer constitution of another example of the light emitting element of the present invention, wherein the light emitting layer is segmented into 4 unit light emitting layers 4a, 4b, 4c and 4d, with 3 intermediate layers 8a, 8b and 8c being disposed respectively between the adjacent unit light emitting layers. The intermediate layer 8a contains a hole blocking material having the lowest hole blocking capacity, the intermediate layer 8c contain a hole blocking material having the highest hole blocking capacity, and the intermediate layer 8b contain a hole blocking material having an intermediate blocking capacity. The total thickness of the 4 unit light emitting layers and 3 intermediate layers in FIG. 4 is substantially the same as that of the light emitting layer shown in FIG. 1.

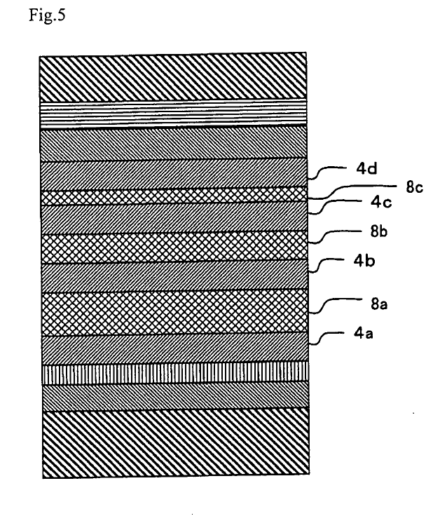

FIG. 5 is a conceptual view of a layer constitution of still another example of the light emitting element of the present invention, wherein the light emitting layer is segmented into 4 unit light emitting layers 4a, 4b, 4c and 4d, with 3 intermediate layers 8a, 8b and 8c being disposed respectively between the adjacent unit light emitting layers. These intermediate layers 8a, 8b and 8c contain an electron blocking material, wherein the layer 8a is the thickest, the layer 8c is the thinnest and the layer 8b has an intermediate thickness. The total thickness of the 4 unit light emitting layers and 3 intermediate layers in FIG. 5 is substantially the same as that of the light emitting layer, shown in FIG. 1.

### 2. Organic EL Element

As a lamination pattern of the organic compound layers according to the present invention, it is preferred that the layers are laminated in the order of a hole injection layer, a light emitting layer, and electron transport layer from the anode side. Moreover, a hole transport layer between the hole injection layer and the light emitting layer and/or an electron transporting intermediate layer between the light emitting layer and the electron transport layer may be provided. In addition, a hole transporting intermediate layer may be provided in between the light emitting layer and the hole transport layer, and similarly, an electron injection layer may be provided in between the cathode and the electron transport layer.

The preferred modes of the organic compound layer in the organic electroluminescence element of the present invention are as follows. (1) An embodiment having a hole injection layer, a hole transport layer (the hole injection layer may also have the role of the hole transport layer), a hole transporting intermediate layer, a light emitting layer, an intermediate layer, an electron transport layer, and an electron injection layer (the electron transport layer may also have the role of the electron injection layer) in this order from the anode side; (2) an embodiment having a hole injection layer, a hole transport layer (the hole injection layer may also have the role of the hole transport layer), a light emitting layer, an intermediate layer, an electron transporting immediate layer, an electron transport layer, and an electron injection layer (the electron transport layer may also have the role of the electron injection layer); and (3) an embodiment having a hole injection layer, a hole transport layer (the hole injection layer may also have the role of the hole transport layer), a hole transporting intermediate layer, a light emitting layer, an intermediate layer, an electron transporting intermediate layer, an electron transport layer, and an electron injection layer (the electron transport layer may also have the role of the electron injection layer).

The above-described hole transporting intermediate layer preferably has at least either a function for accelerating the injection of holes into the light emitting layer, or a function for blocking electrons.

Furthermore, the above-described electron transporting intermediate preferably layer has at least either a function for accelerating the injection of electrons into the light emitting layer, or a function for blocking holes.

Moreover, at least either of the above-described hole transporting intermediate layer and the electron transporting intermediate layer preferably has a function for blocking excitons produced in the light emitting layer.

In order to realize effectively the functions for accelerating the injection of hole, or the injection of electrons, and the functions for blocking holes, electrons, or excitons, it is preferred that the hole transporting intermediate layer and the electron transporting intermediate layer are adjacent to the light emitting layer.

The respective layers mentioned above may be separated into a plurality of secondary layers.

An organic EL element of the invention may have a resonator structure. For instance, on a transparent substrate, a multi-layered film mirror that is made of a plurality of laminated films different in the refractive index, a transparent or translucent electrode, a light emitting layer and a metal electrode are stacked. Light generated in the light emitting layer repeats reflections between the multi-layered film mirror and the metal electrode as reflective plate to resonate.

In another preferable embodiment, on a transparent substrate, a transparent or translucent electrode and a metal electrode, respectively, work as a reflective plate and light generated in a light emitting layer repeats reflections therebetween to resonate.

In order to form a resonant structure, an optical path determined from effective refractive indices of two reflective plates and the refractive indices and thicknesses of the respective layers between the reflective plates is controlled so as to be an optimum value to obtain a desired resonant wave length. A calculation equation in the case of the first embodiment is described in JP-A No. 9-180883. A calculation equation in the case of the second embodiment is described in JP-A No. 2004-127795.

The respective layers that constitute organic compound layers in the present invention can be preferably formed by any method of dry layering methods such as a vapor deposition method and a sputtering method, a transferring method, a printing method, a coating method, a ink jet method, or a spray method.

Next, the components constituting the electroluminescence element of the present invention will be described in detail.

### (Light Emitting Layer)

The light emitting layer is a layer having a function for receiving holes from the anode, the hole injection layer, the hole transport layer or the hole transporting intermediate layer, and receiving electrons from the cathode, the electron injection layer, the electron transport layer, or the electron transporting intermediate layer, and for providing a field for recombination of the holes with the electrons to emit a light.

The light emitting layer of the present invention contains at least a luminescent dopant and a host compound.

The luminescent dopant and the host compound contained in the light emitting layer of the present invention may be either a combination of a fluorescence luminescent dopant in which the luminescence (fluorescence) from a singlet exciton is obtained and the host compound, or a combination of a phosphorescence luminescent dopant in which the luminescence (phosphorescence) from triplet exciton is obtained and the host compound.

The light emitting layer of the present invention may contain two or more types of luminescent dopants for improving color purity and expanding the luminescent wavelength region.

Any of phosphorescent emission materials, fluorescent emission materials and the like may be used as the luminescent dopant in the present invention.

It is preferred that the luminescent dopant in the present invention is one satisfying a relationship between the above-described host compound and the luminescent dopant of 1.2 eV>the difference of Ip between host material and light emitting dopant (ΔIp)>0.2 eV and/or 1.2 eV>the difference of Ea between host material and light emitting dopant (ΔEa)>0.2 eV in view of driving durability.

<<Phosphorescence Luminescent Dopant>>

The phosphorescent emission material are not limited specifically, but generally include complexes containing transition metal atoms or lantanoid atoms.

For instance, although the transition metal atoms are not limited, they are preferably ruthenium, rhodium, palladium, tungsten, rhenium, osmium, iridium, or platinum; more preferably rhenium, iridium, and platinum, or even more preferably iridium, or platinum.

Examples of the lantanoid atoms include lanthanum, cerium, praseodymium, neodymium, samarium, europium, gadolinium, terbium, dysprosium, holmium, erbium, thulium, ytterbium, and lutetium, and among these lantanoid atoms, neodymium, europium, and gadolinium are preferred.

Examples of ligands in the complex include the ligands described, for example, in “Comprehensive Coordination Chemistry” authored by G. Wilkinson et al., published by Pergamon Press Company in 1987; “Photochemistry and Photophysics of Coordination compounds” authored by H. Yersin, published by Springer-Verlag Company in 1987; and “YUHKI KINZOKU KAGAKU—KISO TO OUYOU—(Metalorganic Chemistry—Fundamental and Application—)” authored by Akio Yamamoto, published by Shokabo Publishing Co., Ltd. in 1982.

Specific examples of the ligands include preferably halogen ligands (preferably chlorine ligands), aromatic carboxycyclic ligands (e.g., cyclopentadienyl anions, benzene anions, or naphthyl anions and the like), nitrogen-containing heterocyclic ligands (e.g., phenylpyridine, benzoquinoline, quinolinol, bipyridyl, or phenanthroline and the like), diketone ligands (e.g., acetylacetone and the like), carboxylic acid ligands (e.g., acetic acid ligands and the like), alcoholate ligands (e.g., phenolate ligands and the like), carbon monoxide ligands, isonitryl ligands, and cyano ligand, and more preferably nitrogen-containing heterocyclic ligands.

The above-described complexes may be either a complex containing one transition metal atom in the compound, or a so-called poly-nuclear complex containing two or more transition metal atoms wherein different metal atoms may be contained at the same time.

Among these, specific examples of the luminescent dopants include phosphorescence luminescent compounds described in patent documents such as U.S. Pat. No. 6,303,238B1, U.S. Pat. No. 6,097,147, WO00/57676, WO00/70655, WO01/08230, WO01/39234A2, WO01/41512A1, WO02/02714A2, WO02/15645A1, WO02/44189A1, JP-A No. 2001-247859, Japanese Patent Application No. 2000-33561, JP-A Nos. 2002-117978, 2002-225352, and 2002-235076, Japanese Patent Application No. 2001-239281, JP-A No. 2002-170684, EP1211257, JP-A Nos. 2002-226495, 2002-234894, 2001-247859, 2001-298470, 2002-173674, 2002-203678, 2002-203679, 2004-357791, and 2005-256999, Japanese Patent Application No. 2005-75341, etc.

<<Fluorescence Luminescent Dopant>>

Examples of the above-described fluorescent emission materials include, for example, a benzoxazole derivative, a benzimidazole derivative, a benzothiazole derivative, a styrylbenzene derivative, a polyphenyl derivative, a diphenylbutadiene derivative, a tetraphenylbutadiene derivative, a naphthalimide derivative, a coumarin derivative, a perylene derivative, a perinone derivative, an oxadiazole derivative, an aldazine derivative, a pyralidine derivative, a cyclopentadiene derivative, a bis-styrylanthracene derivative, a quinacridone derivative, a pyrrolopyridine derivative, a thiadiazolopyridine derivative, a styrylamine derivative, aromatic dimethylidene compounds, a variety of metal complexes represented by metal complexes or rare-earth complexes of 8-quinolynol, polymer compounds such as polythiophene, polyphenylene and polyphenylenevinylene, organic silanes, and the like. These compounds may be used singularly or in a combination of two or more.

Among these, specific examples of the luminescent dopants include the following compounds, but it should be noted that the present invention is not limited thereto.

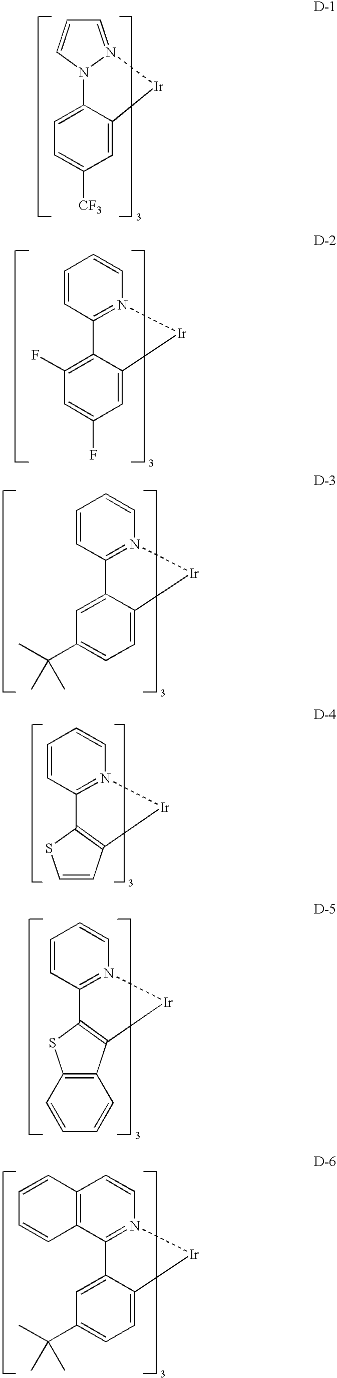

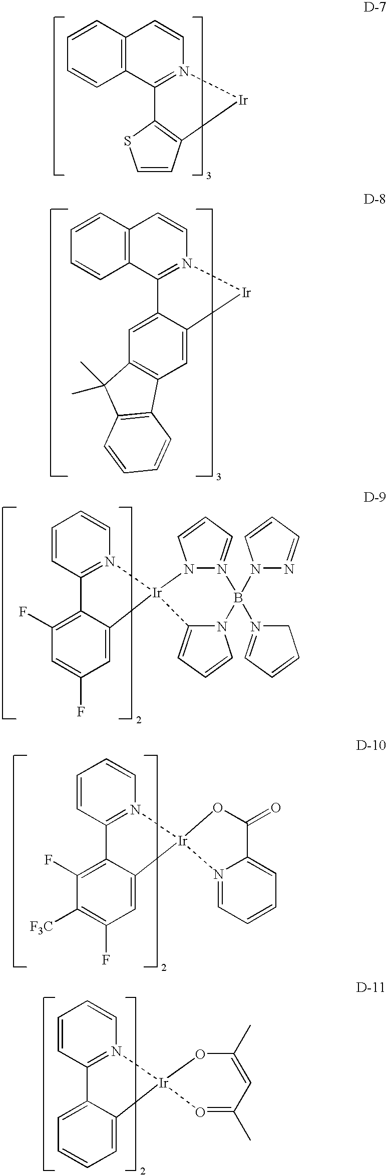

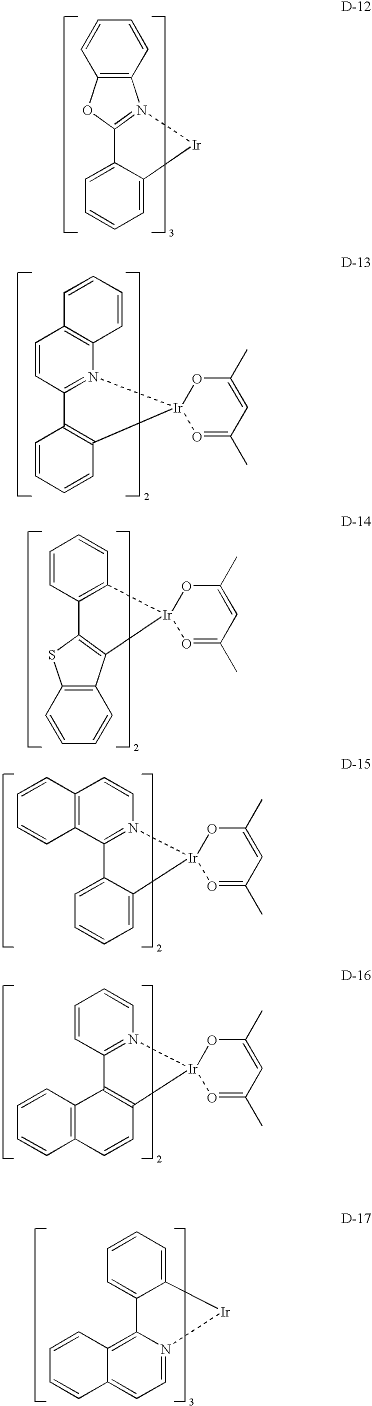

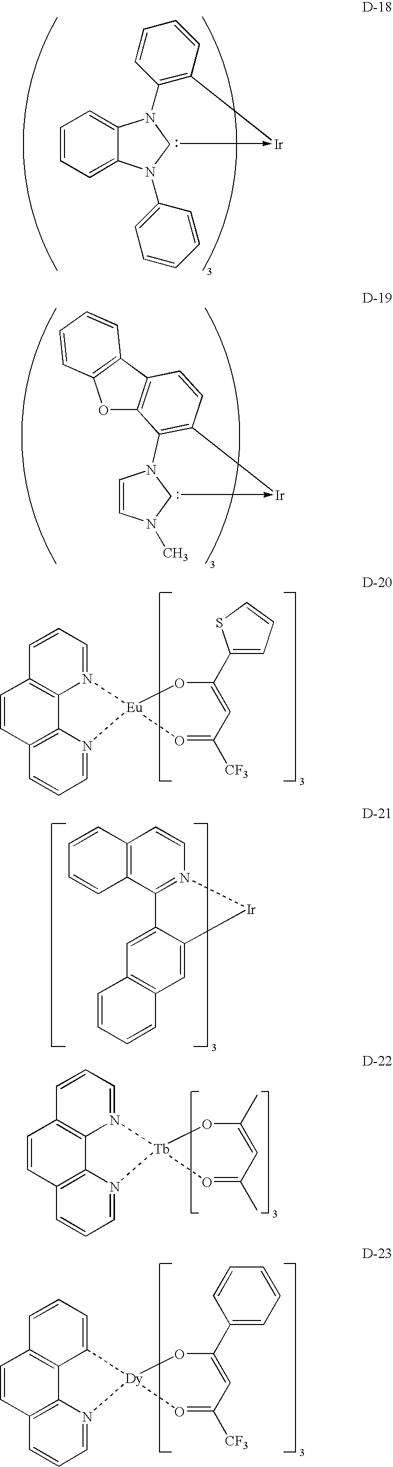

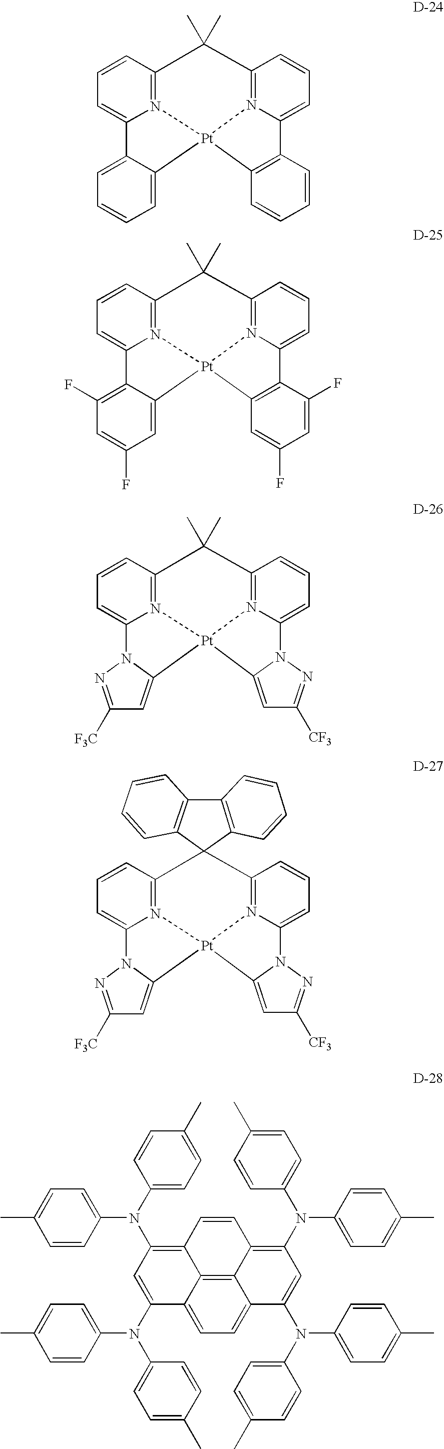

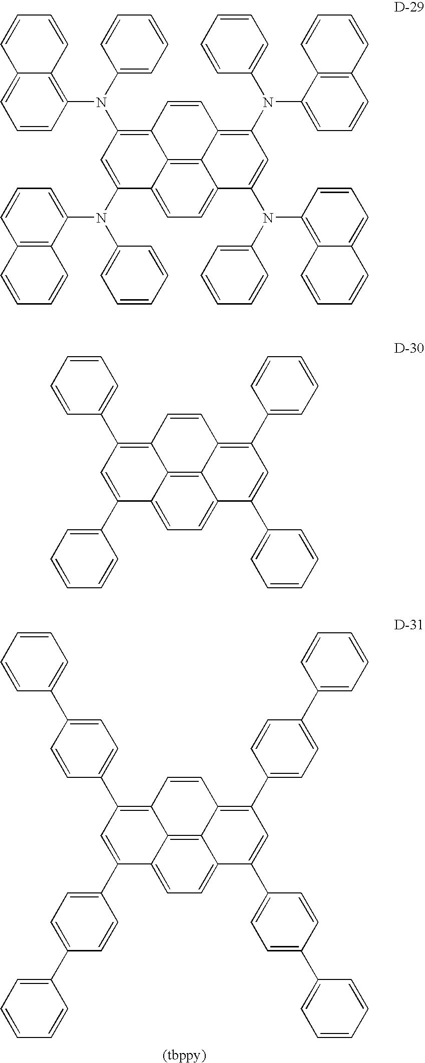

Among the above-described compounds, as the luminescent dopants to be used according to the present invention, D-2 to D-19, and D-24 to D-31 are preferable, D-2 to D-8, D-12, D-14 to D-19, D-24 to D-27, and D-28 to D-31 are more preferable, and D-24 to D-27, and D-28 to D-31 are further preferable in view of external quantum efficiency, and durability.

The luminescent dopant in a light-emitting layer is contained in an amount of 0.1% by volume to 30% by volume with respect to the total mass of the compounds generally forming the light-emitting layer, but it is preferably contained in an amount of 2% by volume to 30% by volume, and more preferably in an amount of 5% by volume to 30% by volume in view of durability and external quantum efficiency.

### (Host Material)

As the host materials to be used according to the present invention, hole transporting host materials excellent in hole transporting property (referred to as a “hole transporting host” in some cases) and electron transporting host compounds excellent in electron transporting property (referred to as an “electron transporting host” in some cases) may be used.

<<Hole Transporting Host>>

The hole transporting host used for the organic layer of the present invention preferably has an ionization potential Ip of 5.1 eV to 6.4 eV, more preferably has an ionization potential of 5.4 eV to 6.2 eV, and further preferably has an ionization potential of 5.6 eV to 6.0 eV in view of improvements in durability and decrease in driving voltage. Furthermore, it preferably has an electron affinity Ea of 1.2 eV to 3.1 eV, more preferably of 1.4 eV to 3.0 eV, and further preferably of 1.8 eV to 2.8 eV in view of improvements in durability and decrease in driving voltage.

Specific examples of such hole transporting hosts as mentioned above include pyrrole, carbazole, azacarbazole, indole, azaindole, pyrazole, imidazole, polyarylalkane, pyrazoline, pyrazolone, phenylenediamine, arylamine, amino-substituted chalcone, styrylanthracene, fluorenone, hydrazone, stilbene, silazane, aromatic tertiary amine compounds, styrylamine compounds, aromatic dimethylidine compounds, porphyrin compounds, polysilane compounds, poly(N-vinylcarbazole), aniline copolymers, electric conductive high-molecular oligomers such as thiophene oligomers, polythiophenes and the like, organic silanes, carbon films, derivatives thereof, and the like.

Among these, indole derivatives, carbazole derivatives, azaindole derivatives, azacarbazole derivatives, aromatic tertiary amine compounds, and thiophene derivatives are preferable, and particularly, compounds containing a plurality of carbazole skeletons, indole skeletons and/or aromatic tertiary amine skeletons in a molecule are preferred.

As specific examples of the hole transporting hosts described above, the following compounds may be listed, but the present invention is not limited thereto.

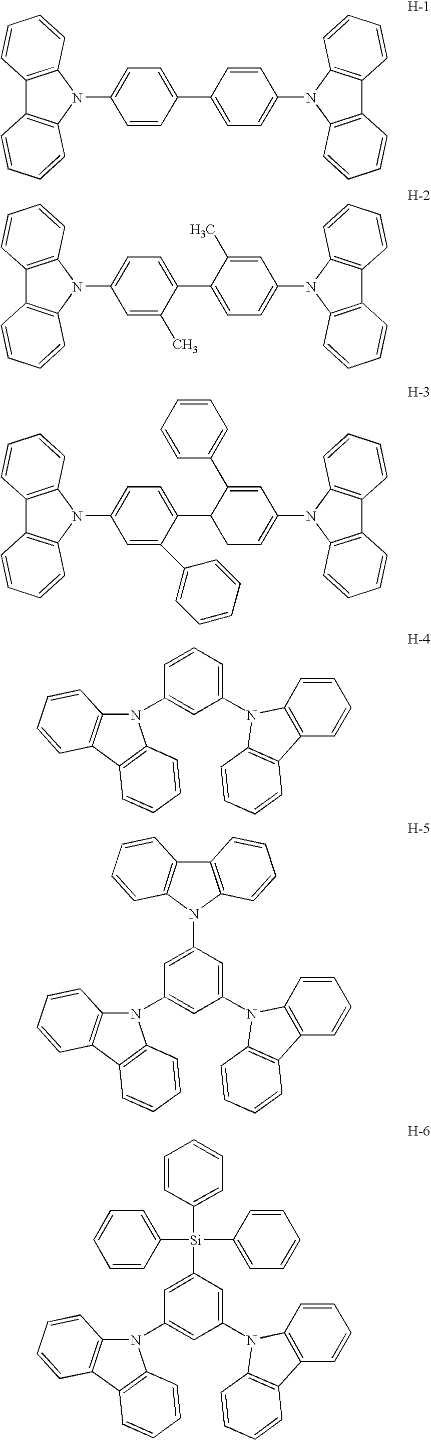

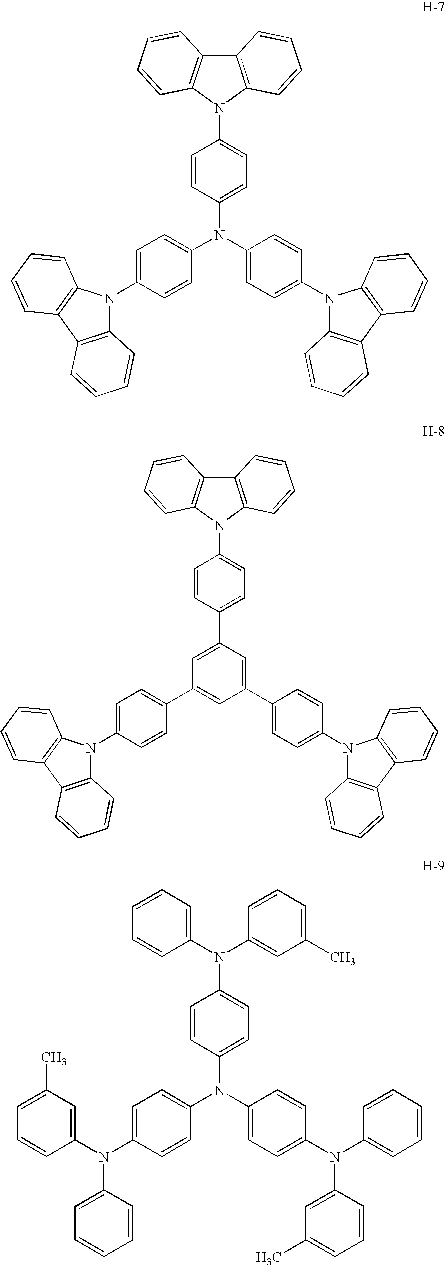

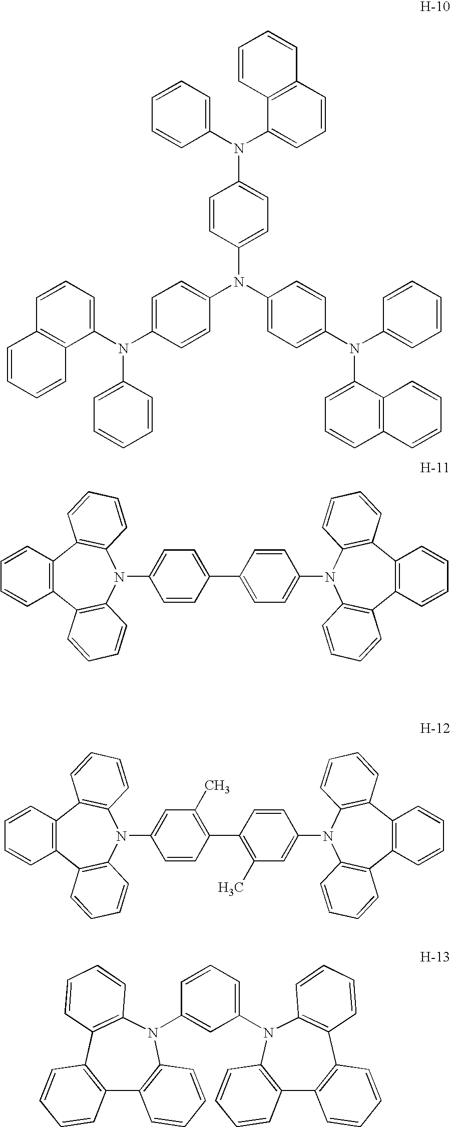

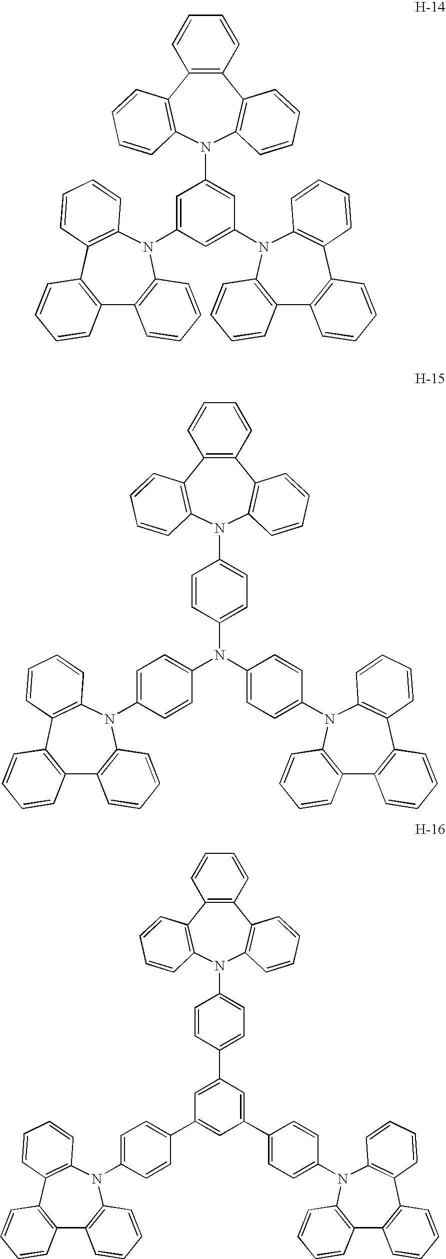

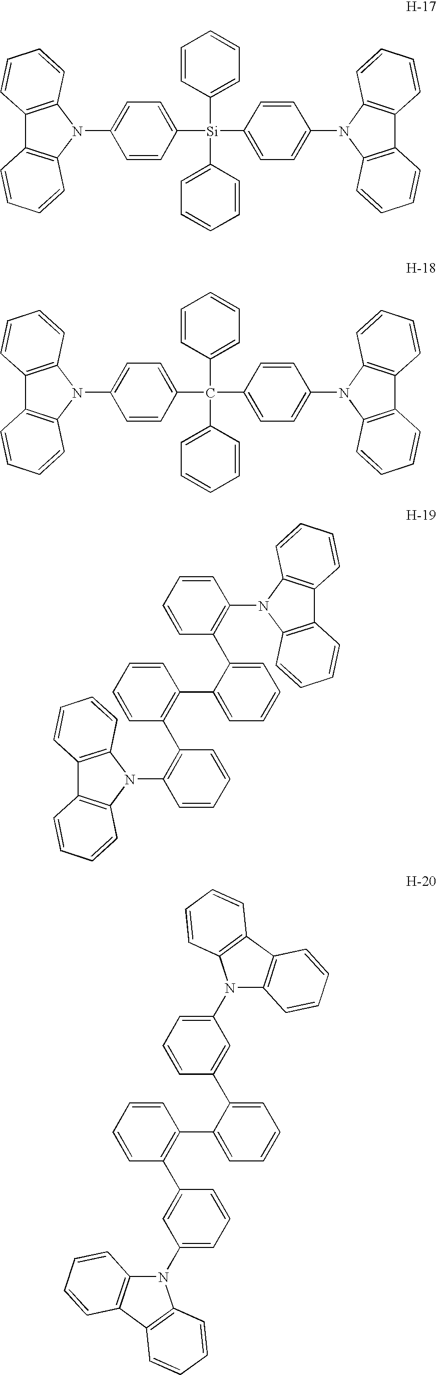

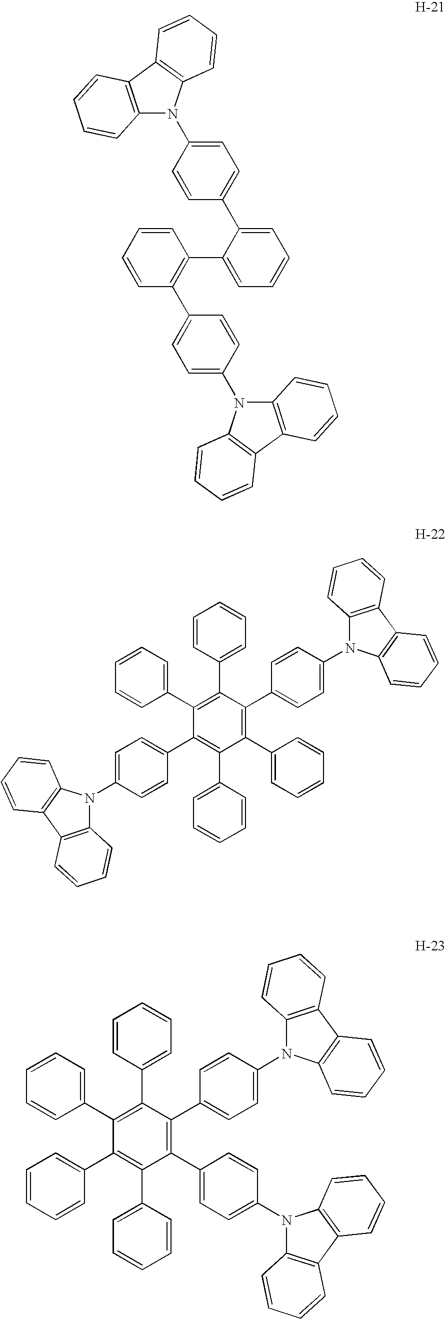

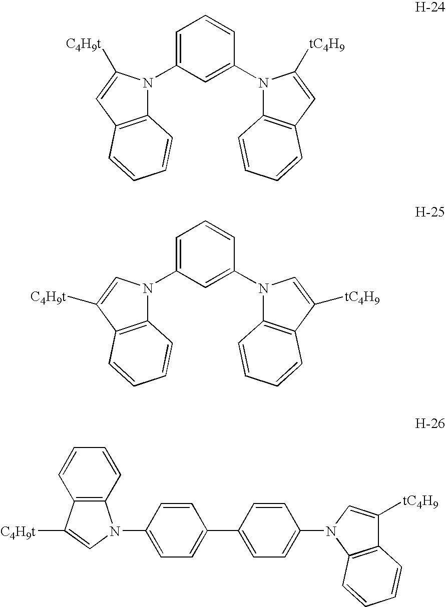

<<Electron Transporting Host>>

As the electron transporting host used according to the present invention, it is preferred that an electron affinity Ea of the host is 2.5 eV to 3.5 eV, more preferably 2.6 eV to 3.4 eV, and further preferably 2.8 eV to 3.3 eV in view of improvements in durability and decrease in driving voltage. Furthermore, it is preferred that an ionization potential Ip of the host is 5.7 eV to 7.5 eV, more preferably 5.8 eV to 7.0 eV, and further preferably 5.9 eV to 6.5 eV in view of improvements in durability and decrease in driving voltage.

Specific examples of such electron transporting hosts as mentioned above include pyridine, pyrimidine, triazine, imidazole, pyrazole, triazole, oxazole, oxadiazole, fluorenone, anthraquinonedimethane, anthrone, diphenylquinone, thiopyrandioxide, carbodiimide, fluorenylidenemethane, distyrylpyradine, fluorine-substituted aromatic compounds, heterocyclic tetracarboxylic anhydrides such as naphthaleneperylene and the like, phthalocyanine, derivatives thereof (which may form a condensed ring with another ring), and a variety of metal complexes represented by metal complexes of 8-quinolynol derivatives, metal phthalocyanine, and metal complexes having benzoxazole or benzothiazole as the ligand.

Preferable electron transporting hosts are metal complexes, azole derivatives (benzimidazole derivatives, imidazopyridine derivatives and the like), and azine derivatives (pyridine derivatives, pyrimidine derivatives, triazine derivatives and the like). Among these, metal complexes are preferred according to the present invention in view of durability. As the metal complex compound, a metal complex containing a ligand having at least one nitrogen atom, oxygen atom, or sulfur atom to be coordinated with the metal is more preferable.

Although a metal ion in the metal complex is not particularly limited, a beryllium ion, a magnesium ion, an aluminum ion, a gallium ion, a zinc ion, an indium ion, a tin ion, a platinum ion, or a palladium ion is preferred; more preferable is a beryllium ion, an aluminum ion, a gallium ion, a zinc ion, a platinum ion, or a palladium ion; and further preferable is an aluminum ion, a zinc ion, or a palladium ion.

Although there are a variety of well-known ligands to be contained in the above-described metal complexes, examples thereof include ligands described in “Photochemistry and Photophysics of Coordination Compounds” authored by H. Yersin, published by Springer-Verlag Company in 1987; “YUHKI KINZOKU KAGAKU—KISO TO OUYOU—(Metalorganic Chemistry—Fundamental and Application—)” authored by Akio Yamamoto, published by Shokabo Publishing Co., Ltd. in 1982; and the like.

The ligands are preferably nitrogen-containing heterocyclic ligands (having preferably 1 to 30 carbon atoms, more preferably 2 to 20 carbon atoms, and particularly preferably 3 to 15 carbon atoms), and they may be a unidentate ligand or a bi- or higher-dentate ligand. Preferable are bi- to hexa-dentate ligands, and mixed ligands of bi- to hexa-dentate ligands with a unidentate ligand are also preferable.

Examples of the ligands include azine ligands (e.g. pyridine ligands, bipyridyl ligands, terpyridine ligands and the like); hydroxyphenylazole ligands (e.g. hydroxyphenylbenzimidazole ligands, hydroxyphenylbenzoxazole ligands, hydroxyphenylimidazole ligands, hydroxyphenylimidazopyridine ligands and the like); alkoxy ligands (those having preferably 1 to 30 carbon atoms, more preferably 1 to 20 carbon atoms, and particularly preferably 1 to 10 carbon atoms, examples of which include methoxy, ethoxy, butoxy, 2-ethylhexyloxy and the like); aryloxy ligands (those having preferably 6 to 30 carbon atoms, more preferably 6 to 20 carbon atoms, and particularly preferably 6 to 12 carbon atoms, examples of which include phenyloxy, 1-naphthyloxy, 2-naphthyloxy, 2,4,6-trimethylphenyloxy, 4-biphenyloxy and the like); heteroaryloxy ligands (those having preferably 1 to 30 carbon atoms, more preferably 1 to 20 carbon atoms, and particularly preferably 1 to 12 carbon atoms, examples of which include pyridyloxy, pyrazyloxy, pyrimidyloxy, quinolyloxy and the like); alkylthio ligands (those having preferably 1 to 30 carbon atoms, more preferably 1 to 20 carbon atoms, and particularly preferably 1 to 12 carbon atoms, examples of which include methylthio, ethylthio and the like); arylthio ligands (those having preferably 6 to 30 carbon atoms, more preferably 6 to 20 carbon atoms, and particularly preferably 6 to 12 carbon atoms, examples of which include phenylthio and the like); heteroarylthio ligands (those having preferably 1 to 30 carbon atoms, more preferably 1 to 20 carbon atoms, and particularly preferably 1 to 12 carbon atoms, examples of which include pyridylthio, 2-benzimidazolylthio, 2-benzooxazolylthio, 2-benzothiazolylthio and the like); siloxy ligands (those having preferably 1 to 30 carbon atoms, more preferably 3 to 25 carbon atoms, and particularly preferably 6 to 20 carbon atoms, examples of which include a triphenylsiloxy group, a triethoxysiloxy group, a triisopropylsiloxy group and the like); aromatic hydrocarbon anion ligands (those having preferably 6 to 30 carbon atoms, more preferably 6 to 25 carbon atoms, and particularly preferably 6 to 20 carbon atoms, examples of which include a phenyl anion, a naphthyl anion, an anthranyl anion and the like anion); aromatic heterocyclic anion ligands (those having preferably 1 to 30 carbon atoms, more preferably 2 to 25 carbon atoms, and particularly preferably 2 to 20 carbon atoms, examples of which include a pyrrole anion, a pyrazole anion, a triazole anion, an oxazole anion, a benzoxazole anion, a thiazole anion, a benzothiazole anion, a thiophene anion, a benzothiophene anion and the like); indolenine anion ligands and the like. Among these, nitrogen-containing heterocyclic ligands, aryloxy ligands, heteroaryloxy groups, aromatic hydrocarbon anion ligands, aromatic heterocyclic anion ligands or siloxy ligands are preferable, and nitrogen-containing heterocyclic ligands, aryloxy ligands, siloxy ligands, aromatic hydrocarbon anion ligands, or aromatic heterocyclic anion ligands are more preferable.

Examples of the metal complex electron transporting hosts include compounds described, for example, in Japanese Patent Application Laid-Open Nos. 2002-235076, 2004-214179, 2004-221062, 2004-221065, 2004-221068, 2004-327313 and the like.

Specific examples of these electron transporting hosts include the following materials, but it should be noted that the present invention is not limited thereto.

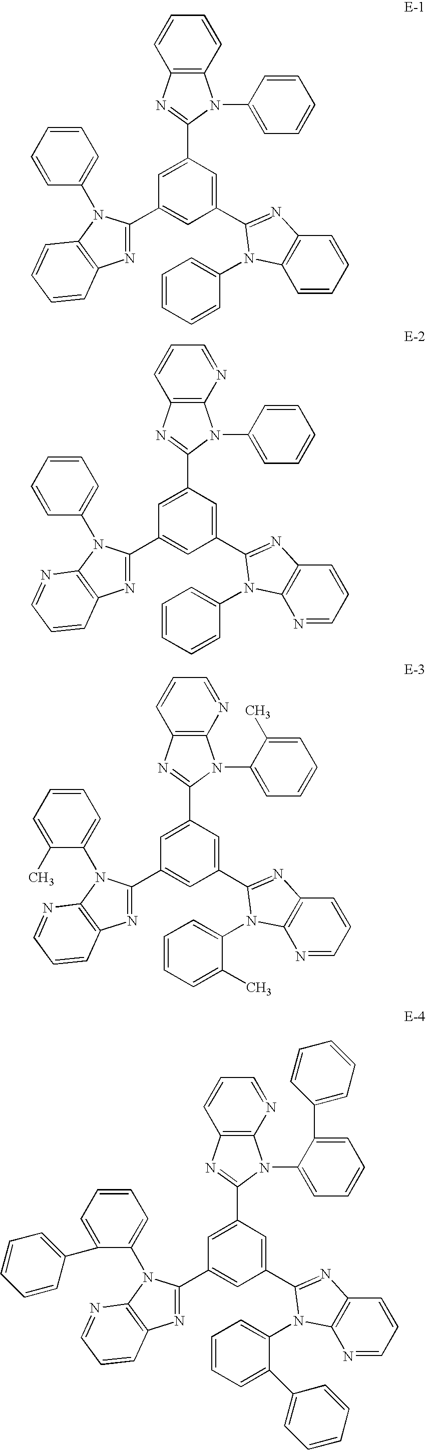

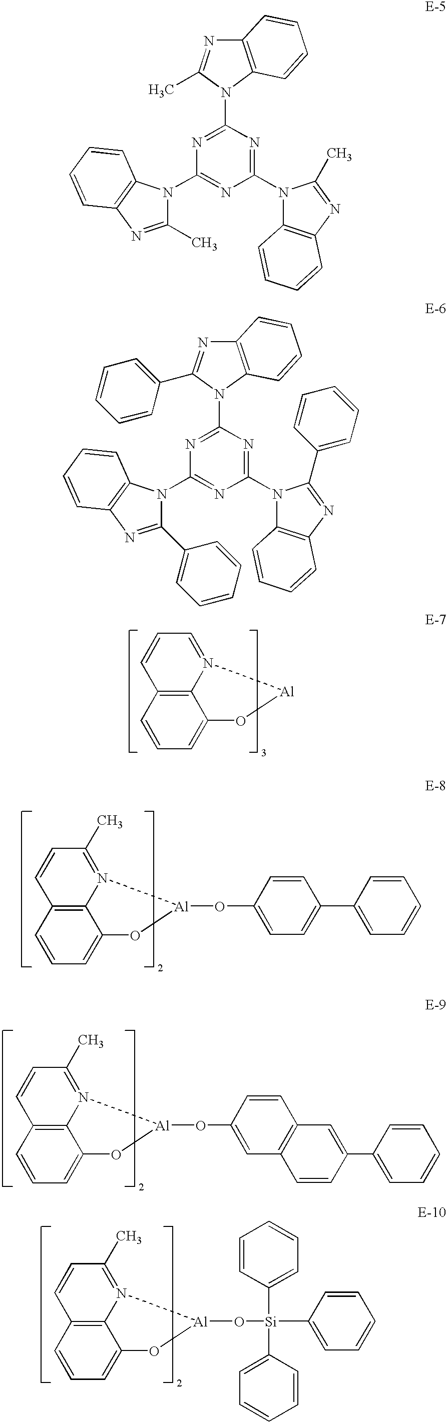

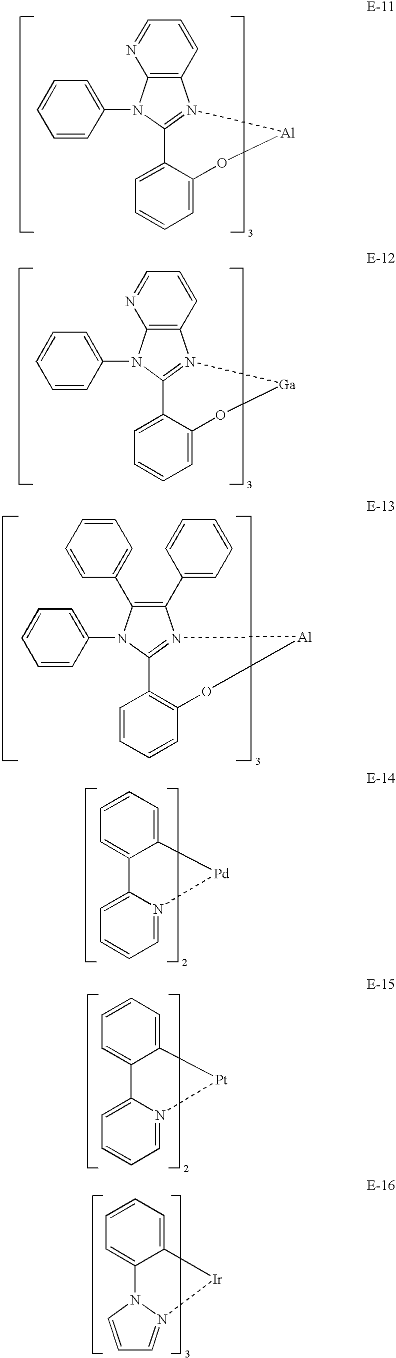

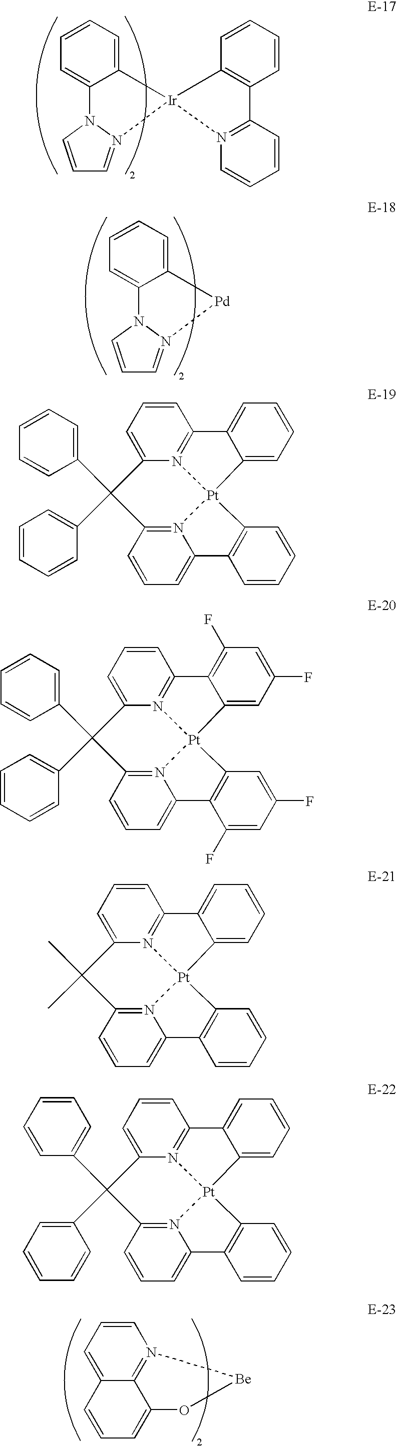

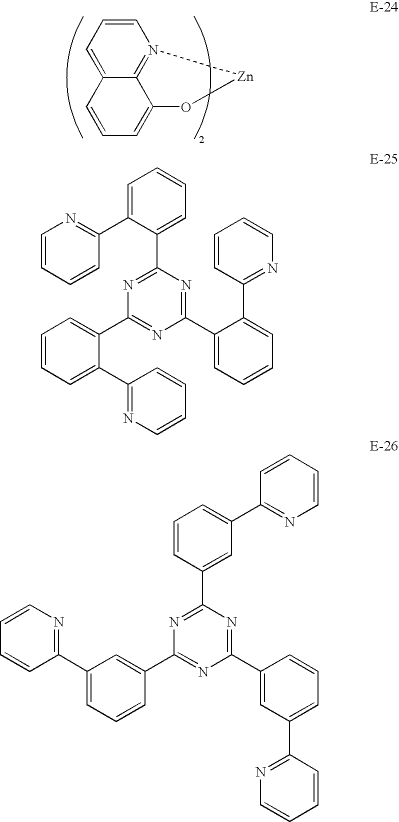

As the electron transportation hosts, E-1 to E-6, E-8, E-9, E-10, E-21, or E-22 is preferred, E-3, E-4, E-6, E-8, E-9, E-10, E-21, or E-22 is more preferred, and E-3, E-4, E-21, or E-22 is further preferred.

In the light-emitting layer of the present invention, it is preferred that when a phosphorescence luminescent dopant is used as the luminescent dopant, the lowest triplet excitation energy T1(D) in the phosphorescence luminescent dopant and the minimum value among the lowest triplet excitation energies T1(H) min in the plural host compounds satisfy the relationship of T1(H) min>T1(D) in view of color purity, external quantum efficiency, and driving durability.

Although a content of the host compounds according to the present invention is not particularly limited, it is preferably 70% by volume to 95% by volume with respect to the total volume of the compounds forming the light-emitting layer in view of external quantum efficiency and driving voltage.

### (Hole Injection Layer and Hole Transport Layer)

The hole injection layer and hole transport layer correspond to layers functioning to receive holes from an anode or from an anode side and to transport the holes to a cathode side.

As an electron-accepting dopant to be introduced into a hole injection layer or a hole transport layer, either of an inorganic compound or an organic compound may be used as long as the compound has electron accepting property and a function for oxidizing an organic compound. Specifically, inorganic compounds such as halides compounds, for example, ferric chloride, aluminum chloride, gallium chloride, indium chloride, antimony pentachloride and the like, and metal oxides such as vanadium pentaoxide, molybdenum trioxide and the like are preferably used as the inorganic compounds.

In case of the organic compounds, compounds having substituents such as a nitro group, a halogen, a cyano group, or a trifluoromethyl group; quinone compounds, acid anhydride compounds, and fullerenes may be preferably applied.

Specific examples of the organic compounds include hexacyanobutadiene, hexacyanobenzene, tetracyanoethylene, tetracyanoquinodimethane, tetrafluorotetracyanoquinodimethane, p-fluoranil, p-chloranil, p-bromanil, p-benzoquinone, 2,6-dichlorobenzoquinone, 2,5-dichlorobenzoquinone, tetramethylbenzoquinone, 1,2,4,5-tetracyanobenzene, o-dicyanobenzene, p-dicyanobenzene, 1,4-dicyanotetrafluorobenzene, 2,3-dichloro-5,6-dicyanobenzoquinone, p-dinitrobenzene, m-dinitrobenzene, o-dinitrobenzene, p-cyanonitrobenzene, m-cyanonitrobenzene, o-cyanonitrobenzene, 1,4-naphthoquinone, 2,3-dichloronaphthoquinone, 1-nitronaphthalene, 2-nitronaphthalene, 1,3-dinitronaphthalene, 1,5-dinitronaphthalene, 9-cyanoanthoracene, 9-nitroanthracene, 9,10-anthraquinone, 1,3,6,8-tetranitrocarbazole, 2,4,7-trinitro-9-fluorenone, 2,3,5,6-tetracyanopyridine, maleic anhydride, phthalic anhydride, fullerene C60, and fullerene C70. Other specific examples include materials described in patent documents such as JP-A Nos. 6-212153, 11-111463, 11-251067, 2000-196140, 2000-286054, 2000-315580, 2001-102175, 2001-160493, 2002-252085, 2002-56985, 2003-157981, 2003-217862, 2003-229278, 2004-342614, 2005-72012, 2005-166637, 2005-209643 and the like.

Among these, hexacyanobutadiene, hexacyanobenzene, tetracyanoethylene, tetracyanoquinodimethane, tetrafluorotetracyanoquinodimethane, p-fluoranil, p-chloranil, p-bromanil, p-benzoquinone, 2,6-dichlorobenzoquinone, 2,5-dichlorobenzoquinone, 1,2,4,5-tetracyanobenzene, 1,4-dicyanotetrafluorobenzene, 2,3-dichloro-5,6-dicyanobenzoquinone, p-dinitrobenzene, m-dinitrobenzene, o-dinitrobenzene, 1,4-naphthoquinone, 2,3-dichloronaphthoquinone, 1,3-dinitronaphthalene, 1,5-dinitronaphthalene, 9,10-anthraquinone, 1,3,6,8-tetranitrocarbazole, 2,4,7-trinitro-9-fluorenone, 2,3,5,6-tetracyanopyridine, or fullerene C60 is preferable. Hexacyanobutadiene, hexacyanobenzene, tetracyanoethylene, tetracyanoquinodimethane, tetrafluorotetracyanoquinodimethane, p-fluoranil, p-chloranil, p-bromanil, 2,6-dichlorobenzoquinone, 2,5-dichlorobenzoquinone, 2,3-dichloronaphthoquinone, 1,2,4,5-tetracyanobenzene, 2,3-dichloro-5,6-dicyanobenzoquinone, or 2,3,5,6-tetracyanopyridine is particularly preferred, and tetrafluorotetracyanoquinodimethane is most particularly preferred.

These electron-accepting dopants may be used alone or in a combination of two or more of them.

Although an applied amount of these electron-accepting dopants depends on the type of material, 0.01% by mass to 50% by mass of a dopant is preferred with respect to a hole transport layer material, 0.05% by mass to 20% by mass is more preferable, and 0.1% by mass to 10% by mass is particularly preferred. When the amount applied is less than 0.01% by mass with respect to the hole transportation material, it is not desirable because the advantageous effects of the present invention are insufficient, and when it exceeds 50% by mass, hole transportation ability is deteriorated, and thus, this is not preferred.

In a case where the hole injection layer contains an acceptor, it is preferred that the hole transport layer has no substantial acceptor.

As a material for the hole injection layer and the hole transport layer, it is preferred to contain specifically pyrrole derivatives, carbazole derivatives, azacarbazole derivatives, indole derivatives, azaindole derivatives, pyrazole derivatives, imidazole derivatives, polyarylalkane derivatives, pyrazoline derivatives, pyrazolone derivatives, phenylenediamine derivatives, arylamine derivatives, amino-substituted calcon derivatives, styrylanthracene derivatives, fluorenone derivatives, hydrazone derivatives, stilbene derivatives, silazane derivatives, aromatic tertiary amine compounds, styrylamine derivatives, aromatic dimethylidine compounds, porphyrin compounds, organosilane derivatives, carbon or the like.

Although a thickness of the hole injection layer and the hole transport layer is not particularly limited, it is preferred that the thickness is 1 nm to 5 μm, it is more preferably 5 nm to 1 μm, and 10 nm to 500 nm is particularly preferred in view of decrease in driving voltage, improvements in luminescent efficiency, and improvements in durability.

The hole injection layer and the hole transport layer may be composed of a mono-layered structure comprising one or two or more of the above-mentioned materials, or a multilayer structure composed of plural layers of a homogeneous composition or heterogeneous compositions.

When the carrier transportation layer adjacent to the light emitting layer is a hole transport layer, it is preferred that the Ip (HTL) of the hole transport layer is smaller than the Ip (D) of the dopant contained in the light emitting layer in view of driving durability.

The Ip (HTL) in the hole transport layer may be measured in accordance with the below-mentioned measuring method of Ip.

A carrier mobility in the hole transport layer is usually from 10⁻⁷ cm²·V⁻¹·s⁻¹ to 10⁻¹ cm²·V⁻¹·s⁻¹; and in this range, from 10⁻⁵ cm²·V⁻¹·s⁻¹ to 10⁻¹ cm²·V⁻¹·s⁻¹ is preferable; from 10⁻⁴ cm²·V⁻¹·s⁻¹ to 10⁻¹ cm²·V⁻¹·s⁻¹ is more preferable; and from 10⁻³ cm²·V⁻¹·s⁻¹ to 10⁻¹ cm²·V⁻¹·s⁻¹ is particularly preferable in view of the luminescent efficiency.

For the carrier mobility, a value measured in accordance with the same method as that of the carrier mobility of the above-described light emitting layer is adopted.

Moreover, it is preferred that the carrier mobility in the hole transport layer is higher than that in the above-described light emitting layer in view of driving durability and luminescent efficiency.

### (Electron Injection Layer and Electron Transport Layer)

The electron injection layer and the electron transport layer are layers having any of functions for injecting electrons from the cathode, transporting electrons, and becoming a barrier to holes which could be injected from the anode.

As a material applied for the electron-donating dopant with respect to the electron injection layer or the electron transport layer, any material may be used as long as it has an electron-donating property and a property for reducing an organic compound, and alkaline metals such as Li, alkaline earth metals such as Mg, and transition metals including rare-earth metals are preferably used.

Particularly, metals having a work function of 4.2 eV or less are preferably applied, and specific examples thereof include Li, Na, K, Be, Mg, Ca, Sr, Ba, Y, Cs, La, Sm, Gd, and Yb.

These electron-donating dopants may be used alone or in a combination of two or more of them.

An applied amount of the electron-donating dopants differs dependent on the types of the materials, but it is preferably 0.1% by mass to 99% by mass with respect to an electron transport layer material, more preferably 1.0% by mass to 80% by mass, and particularly preferably 2.0% by mass to 70% by mass. When the amount applied is less than 0.1% by mass, the efficiency of the present invention is insufficient so that it is not desirable, and when it exceeds 99% by mass, the electron transportation ability is deteriorated so that it is not preferred.

Specific examples of the materials applied for the electron injection layer and the electron transport layer include pyridine, pyrimidine, triazine, imidazole, triazole, oxazole, oxadiazole, fluorenone, anthraquinodimethane, anthrone, diphenylquinone, thiopyrandioxide, carbodiimide, fluorenylidenemethane, distyrylpyradine, fluorine-substituted aromatic compounds, naphthalene, heterocyclic tetracarboxylic anhydrides such as perylene, phthalocyanine, and the derivatives thereof (which may form condensed rings with the other rings); and metal complexes represented by metal complexes of 8-quinolinol derivatives, metal phthalocyanine, and metal complexes containing benzoxazole, or benzothiazole as the ligand.

Although a thickness of the electron injection layer and the electron transport layer is not particularly limited, it is preferred that the thickness is in 1 nm to 5 μm, it is more preferably 5 nm to 1 μm, and it is particularly preferably 10 nm to 500 nm in view of decrease in driving voltage, improvements in luminescent efficiency, and improvements in durability.

The electron injection layer and the electron transport layer may have either a mono-layered structure comprising one or two or more of the above-mentioned materials, or a multilayer structure composed of plural layers of a homogeneous composition or a heterogeneous composition.

When the carrier transportation layer adjacent to the light emitting layer is an electron transport layer, it is preferred that the Ea (ETL) of the electron transport layer is higher than the Ea (D) of the dopants contained in the light emitting layer in view of driving durability.

For the Ea (ETL), a value measured in accordance with the same manner as the measuring method of Ea, which will be mentioned later, is used.

Furthermore, the carrier mobility in the electron transport layer is usually from 10⁻⁷ cm²·V⁻¹·s⁻¹ to 10⁻¹ cm²·V⁻¹·s⁻¹, and in this range, from 10⁻⁵ cm²·V⁻¹·s⁻¹ to 10⁻¹ cm²·V⁻¹·s⁻¹ is preferable, from 10⁻⁴ cm²·V⁻¹·s⁻¹ to 10⁻¹ cm²·V⁻¹·s⁻¹ is more preferable, and from 10⁻³ cm²·V⁻¹·s⁻¹ to 10⁻¹ cm²·V⁻¹·s⁻¹ is particularly preferred, in view of luminescent efficiency.

Moreover, it is preferred that the carrier mobility in the electron transport layer is higher than that of the light emitting layer in view of driving durability. The carrier mobility is measured in accordance with the same method as that of the hole transport layer.

As to the carrier mobility of the luminescence element of the present invention, it is preferred that the carrier mobility in the hole transport layer, the electron transport layer, and the light emitting layer has the relationship of (electron transport layer≧hole transport layer)>light emitting layer in view of driving durability.

### (Hole Blocking Layer)

A hole blocking layer is a layer having a function to prevent the holes transported from the anode to the light emitting layer from passing through to the cathode side. According to the present invention, a hole blocking layer may be provided as an organic compound layer adjacent to the light emitting layer on the cathode side.

The hole blocking layer is not particularly limited, but specifically, it may contain an aluminum complex such as BAlq, a triazole derivative, a pyrazabol derivative or the like.

It is preferred that a thickness of the hole blocking layer is generally 50 nm or less in order to lower the driving voltage, more preferably it is 1 nm to 50 nm, and further preferably it is 5 nm to 40 nm.

### (Anode)

The anode may generally be any material as long as it has a function as an electrode for supplying holes to the organic compound layer, and there is no particular limitation as to the shape, the structure, the size or the like. However, it may be suitably selected from among well-known electrode materials according to the application and purpose of luminescence element. As mentioned above, the anode is usually provided as a transparent anode.

Materials for the anode may preferably include, for example, metals, alloys, metal oxides, electric-conductive compounds, and mixtures thereof, and those having a work function of 4.0 eV or more are preferred. Specific examples of the anode materials include electro-conductive metal oxides such as tin oxides doped with antimony, fluorine or the like (ATO and FTO), tin oxide, zinc oxide, indium oxide, indium tin oxide (ITO), and indium zinc oxide (IZO); metals such as gold, silver, chromium, and nickel; mixtures or laminates of these metals and the electric-conductive metal oxides; inorganic electric-conductive materials such as copper iodide and copper sulfide; organic electro-conductive materials such as polyaniline, polythiophene, and polypyrrole; and laminates of these inorganic or organic electron-conductive materials with ITO. Among these, the electro-conductive metal oxides are preferred, and particularly, ITO is preferable in view of productivity, high electric-conductivity, transparency and the like.

The anode may be formed on the substrate in accordance with a method which is appropriately selected from among wet methods such as printing methods, coating methods and the like; physical methods such as vacuum deposition methods, sputtering methods, ion plating methods and the like; and chemical methods such as CVD and plasma CVD methods and the like, in consideration of the suitability to a material constituting the anode. For instance, when ITO is selected as a material for the anode, the anode may be formed in accordance with a DC or high-frequency sputtering method, a vacuum deposition method, an ion plating method or the like.

In the organic electroluminescence element of the present invention, a position at which the anode is to be formed is not particularly limited, but it may be suitably selected according to the application and purpose of the luminescence element. The anode may be formed on either the whole surface or a part of the surface on either side of the substrate.

For patterning to form the anode, a chemical etching method such as photolithography, a physical etching method such as etching by laser, a method of vacuum deposition or sputtering through superposing masks, or a lift-off method or a printing method may be applied.

A thickness of the anode may be suitably selected according to the material constituting the anode and is therefore not definitely decided, but it is usually in the range of around 10 nm to 50 μm, and preferably 50 nm to 20 μm.

A value of resistance of the anode is preferably 10³ Ω/□ or less, and 10² Ω/□ or less is more preferable. In the case where the anode is transparent, it may be either transparent and colorless, or transparent and colored. For extracting luminescence from the transparent anode side, it is preferred that a light transmittance of the anode is 60% or higher, and more preferably 70% or higher.

Concerning transparent anodes, there is a detailed description in “TOUMEI DENNKYOKU-MAKU NO SHINTENKAI (Novel Developments in Transparent Electrode Films)” edited by Yutaka Sawada, published by C.M.C. in 1999, the contents of which are incorporated by reference herein. In the case where a plastic substrate having a low heat resistance is applied, it is preferred that ITO or IZO is used to obtain a transparent anode prepared by forming the film at a low temperature of 150° C. or lower.

### (Cathode)

The cathode may generally be any material as long as it has a function as an electrode for injecting electrons to the organic compound layer, and there is no particular limitation as to the shape, the structure, the size or the like. However it may be suitably selected from among well-known electrode materials according to the application and purpose of the luminescence element.

Materials constituting the cathode may include, for example, metals, alloys, metal oxides, electric-conductive compounds, and mixtures thereof, and materials having a work function of 4.5 eV or less are preferred. Specific examples thereof include alkali metals (e.g., Li, Na, K, Cs or the like), alkaline earth metals (e.g., Mg, Ca or the like), gold, silver, lead, aluminum, sodium-potassium alloys, lithium-aluminum alloys, magnesium-silver alloys, rare earth metals such as indium, and ytterbium, and the like. They may be used alone, but it is preferred that two or more of them are used in combination from the viewpoint of satisfying both stability and electron injectability.

Among these, as the materials for constituting the cathode, alkaline metals or alkaline earth metals are preferred in view of electron injectability, and materials containing aluminum as a major component are preferred in view of excellent preservation stability.

The term “material containing aluminum as a major component” refers to a material constituted by aluminum alone; alloys comprising aluminum and 0.01% by mass to 10% by mass of an alkaline metal or an alkaline earth metal; or the mixtures thereof (e.g., lithium-aluminum alloys, magnesium-aluminum alloys and the like).

Regarding materials for the cathode, they are described in detail in JP-A Nos. 2-15595 and 5-121172, of which are incorporated by reference herein.

A method for forming the cathode is not particularly limited, but it may be formed in accordance with a well-known method.

For instance, the cathode may be formed in accordance with a method which is appropriately selected from among wet methods such as printing methods, coating methods and the like; physical methods such as vacuum deposition methods, sputtering methods, ion plating methods and the like; and chemical methods such as CVD and plasma CVD methods and the like, in consideration of the suitability to a material constituting the cathode. For example, when a metal (or metals) is (are) selected as a material (or materials) for the cathode, one or two or more of them may be applied at the same time or sequentially in accordance with a sputtering method or the like.

For patterning to form the cathode, a chemical etching method such as photolithography, a physical etching method such as etching by laser, a method of vacuum deposition or sputtering through superposing masks, or a lift-off method or a printing method may be applied.

In the present invention, a position at which the cathode is to be formed is not particularly limited, and it may be formed on either the whole or a part of the organic compound layer.

Furthermore, a dielectric material layer made of fluorides, oxides or the like of an alkaline metal or an alkaline earth metal may be inserted in between the cathode and the organic compound layer with a thickness of 0.1 nm to 5 nm. The dielectric layer may be considered to be a kind of electron injection layer. The dielectric material layer may be formed in accordance with, for example, a vacuum deposition method, a sputtering method, an ion-plating method or the like.

A thickness of the cathode may be suitably selected according to materials for constituting the cathode and is therefore not definitely decided, but it is usually in the range of around 10 nm to 5 μm, and preferably 50 nm to 1 μm.

Moreover, the cathode may be transparent or opaque. The transparent cathode may be formed by preparing a material for the cathode with a small thickness of 1 nm to 10 nm, and further laminating a transparent electric-conductive material such as ITO or IZO thereon.

### (Substrate)

According to the present invention, a substrate may be applied. The substrate to be applied is preferably one which does not scatter or attenuate light emitted from the organic compound layer. Specific examples of materials for the substrate include zirconia-stabilized yttrium (YSZ); inorganic materials such as glass; polyesters such as polyethylene terephthalate, polybutylene phthalate, and polyethylene naphthalate; and organic materials such as polystyrene, polycarbonate, polyethersulfon, polyarylate, polyimide, polycycloolefin, norbornene resin, poly(chlorotrifluoroethylene), and the like.

For instance, when glass is used as the substrate, non-alkali glass is preferably used with respect to the quality of material in order to decrease ions eluted from the glass. In the case of employing soda-lime glass, it is preferred to use glass on which a barrier coat such as silica has been applied. In the case of employing an organic material, it is preferred to use a material excellent in heat resistance, dimension stability, solvent resistance, electrical insulation, and workability.

There is no particular limitation as to the shape, the structure, the size or the like of the substrate, but it may be suitably selected according to the application, purposes and the like of the luminescence element. In general, a plate-like substrate is preferred as the shape of the substrate. A structure of the substrate may be a monolayer structure or a laminated structure. Furthermore, the substrate may be formed from a single member or two or more members.

Although the substrate may be in a transparent and colorless, or a transparent and colored condition, it is preferred that the substrate is transparent and colorless from the viewpoint that the substrate does not scatter or attenuate light emitted from the organic light emitting layer.

A moisture permeation preventive layer (gas barrier layer) may be provided on the front surface or the back surface of the substrate.

For a material of the moisture permeation preventive layer (gas barrier layer), inorganic substances such as silicon nitride and silicon oxide may be preferably applied. The moisture permeation preventive layer (gas barrier layer) may be formed in accordance with, for example, a high-frequency sputtering method or the like.

In the case of applying a thermoplastic substrate, a hard-coat layer or an under-coat layer may be further provided as needed.

### (Protective Layer)

According to the present invention, the whole organic EL element may be protected by a protective layer.

A material contained in the protective layer may be one having a function to prevent penetration of substances such as moisture and oxygen, which accelerate deterioration of the device, into the device.

Specific examples thereof include metals such as In, Sn, Pb, Au, Cu, Ag, Al, Ti, Ni and the like; metal oxides such as MgO, SiO, SiO₂, Al₂O₃, GeO, NiO, CaO, BaO, Fe₂O₃, Y₂O₃, TiO₂ and the like; metal nitrides such as SiNₓ, SiNₓO_{y} and the like; metal fluorides such as MgF₂, LiF, AlF₃, CaF₂ and the like; polyethylene; polypropylene; polymethyl methacrylate; polyimide; polyurea; polytetrafluoroethylene; polychlorotrifluoroethylene; polydichlorodifluoroethylene; a copolymer of chlorotrifluoroethylene and dichlorodifluoroethylene; copolymers obtained by copolymerizing a monomer mixture containing tetrafluoroethylene and at least one co-monomer; fluorine-containing copolymers each having a cyclic structure in the copolymerization main chain; water-absorbing materials each having a coefficient of water absorption of 1% or more; moisture permeation preventive substances each having a coefficient of water absorption of 0.1% or less; and the like.

There is no particular limitation as to a method for forming the protective layer. For instance, a vacuum deposition method, a sputtering method, a reactive sputtering method, an MBE (molecular beam epitaxial) method, a cluster ion beam method, an ion plating method, a plasma polymerization method (high-frequency excitation ion plating method), a plasma CVD method, a laser CVD method, a thermal CVD method, a gas source CVD method, a coating method, a printing method, or a transfer method may be applied.

### (Sealing)

The whole organic electroluminescence element of the present invention may be sealed with a sealing cap.

Furthermore, a moisture absorbent or an inert liquid may be used to seal a space defined between the sealing cap and the luminescence element. Although the moisture absorbent is not particularly limited. Specific examples thereof include barium oxide, sodium oxide, potassium oxide, calcium oxide, sodium sulfate, calcium sulfate, magnesium sulfate, phosphorus pentoxide, calcium chloride, magnesium chloride, copper chloride, cesium fluoride, niobium fluoride, calcium bromide, vanadium bromide, molecular sieve, zeolite, magnesium oxide and the like. Although the inert liquid is not particularly limited, specific examples thereof include paraffins; liquid paraffins; fluorine-based solvents such as perfluoroalkanes, perfluoroamines, perfluoroethers and the like; chlorine-based solvents; silicone oils; and the like.

### 3. Driving

In the organic electroluminescence element of the present invention, when a DC (AC components may be contained as needed) voltage (usually 2 volts to 15 volts) or DC is applied across the anode and the cathode, luminescence can be obtained.

The driving durability of the organic electroluminescence element according to the present invention can be determined based on the brightness halftime at a specified brightness. For instance, the brightness halftime may be determined by using a source measure unit, model 2400, manufactured by KEITHLEY to apply a DC voltage to the organic EL element to cause it to emit light, conducting a continuous driving test under the condition that the initial brightness is 1500 cd/m² for green light emission, or 360 cd/m² for red or blue light emission, defining the time required for the brightness to reach 80% to the initial brightness as the brightness decaying time, and then comparing the resulting brightness decaying time with that of a conventional luminescence element. According to the present invention, the numerical value thus obtained was used.

An important characteristic parameter of the organic electroluminescence element of the present invention is external quantum efficiency. The external quantum efficiency is calculated by “the external quantum efficiency (φ)=the number of photons emitted from the element/the number of electrons injected to the element”, and it may be said that the larger the value obtained is, the more advantageous the device is in view of electric power consumption.

Moreover, the external quantum efficiency of the organic electroluminescence element is decided by “the external quantum efficiency (φ)=the internal quantum efficiency×light-extraction efficiency”. In an organic EL element which utilizes the fluorescent luminescence from the organic compound, an upper limit of the internal quantum efficiency is 25%, while the light-extraction efficiency is about 20%, and accordingly, it is considered that an upper limit of the external quantum efficiency is about 5%.

As the numerical value of the external quantum efficiency, the maximum value thereof when the device is driven at 20° C., or a value of the external quantum efficiency at about 100 cd/m² to 2000 cd/m² (preferably, 500 cd/m² in the case of red light emission, 1500 cd/m² in the case of green light emission, and 360 cd/m² in the case of blue light emission), may be used.

According to the present invention, a value obtained by the following method is used. Namely, a DC constant voltage is applied to the EL device by the use of a source measure unit, model 2400, manufactured by KEITHLEY to cause it to emit light, the brightness of the light is measured by using a brightness photometer (trade name: SR-3, manufactured by Topcon Corporation), and then, the external quantum efficiency at the luminescent brightness is calculated.

Further, an external quantum efficiency of the luminescence element may be obtained by measuring the luminescent brightness, the luminescent spectrum, and the current density, and calculating the external quantum efficiency from these results and a specific visibility curve. In other words, using the current density value, the number of electrons injected can be calculated. By an integration calculation using the luminescent spectrum and the specific visibility curve (spectrum), the luminescent brightness can be converted into the number of photons emitted. From the result, the external quantum efficiency (%) can be calculated by “(the number of photons emitted from the element/the number of electrons injected to the element)×100”.

For the driving method of the organic electroluminescence element of the present invention, driving methods described in JP-A Nos. 2-148687, 6-301355, 5-29080, 7-134558, 8-234685, and 8-241047; Japanese Patent No. 2784615, U.S. Pat. Nos. 5,828,429, 6,023,308 and the like are applicable.

### 4. Application

The application of the light emitting element in the present invention is not particularly restricted, but can be appropriately used for displays for portable phone, personal digital assistants (PDA), computer displays, car communication displays for motor car, TV monitors, or conventional illumination light sources and the like.

### EXAMPLES

In the following, examples of the organic electroluminescence element of the present invention will be described, but it should be noted that the present invention is not limited to these examples.

### Example 1

### 1. Preparation of Organic EL Element

### (Preparation of Comparative Organic EL Element No. 1)

A 2.5 cm square ITO glass substrate having a 0.5 mm thickness (manufactured by Geomatec Co., Ltd.; surface resistance: 10 Ω/□) was placed in a washing container to apply ultrasonic cleaning in 2-propanol, and then, UV-ozone treatment was applied for 30 minutes. On this transparent anode, the following layers were deposited in accordance with a vacuum deposition method. In the examples of the present invention, a deposition rate was 0.2 nm/second, unless otherwise specified, wherein the deposition rate was measured by the use of a quartz oscillator. The thicknesses of layers described below were also measured by using the quartz oscillator.

—Hole Injection Layer—

On the ITO layer, CuPc was deposited by the evaporation method at a thickness of 10 nm.

—Hole Transport Layer—

On the hole injection layer, α-NPD was deposited by the evaporation method at a thickness of 10 nm.

—Light Emitting Layer—

CBP and Ir(ppy)₃ were co-deposited at a volume ratio of 95:5. The thickness of the light emitting layer was 90 nm.

—Electron Transport Layer—

BAlq was deposited by the evaporation method at a thickness of 10 nm.

—Electron Injection Layer—

Alq was deposited by the evaporation method at a thickness of 20 nm.

On the resulting layers, a patterned mask (mask by which the light emitting region becomes 2 mm×2 mm) was disposed, and lithium fluoride was deposited at a thickness of 1 nm at a deposition rate of 0.01 nm/second to obtain an electron injection layer. Further, metal aluminum was deposited thereon with a 100 nm thickness to obtain a cathode.

The prepared lamination body was placed in a globe box whose the contents were replaced by nitrogen gas, and it was sealed by the use of a sealing cap made of stainless steel and a UV curable adhesive (trade name: XNR5516HV, manufactured by Nagase-Ciba Co., Ltd.).

Thus, the comparative organic EL element No. 1 was obtained.

### (Preparation of Comparative Organic EL Element No. 1A)

In the process of preparing the comparative organic EL element No. 1, the light-emitting layer was divided into three unit light-emitting layers as shown below, and between the respective unit light-emitting layers, intermediate layers 1 and 2 having a charge blocking capacity were disposed shown below. Sequentially from a hole transporting layer, a unit light-emitting layer 1/an intermediate layer 1/a unit light-emitting layer 2/an intermediate layer 2/a unit light-emitting layer 3 were disposed.

Unit light-emitting layer 1: a light-emitting layer having a composition the same as that of comparative example 1 was vapor deposited at a film thickness of 20 nm.

Intermediate Layer 1: <Example of Intermediate Layer Containing Electron Blocking Material>

A hole transporting material B that becomes an electron blocking material and Ir(ppy)₃ were co-deposited at a volume ratio of 95:5 to form an intermediate layer.

Since an Ea value of the hole transporting material B that becomes an electron blocking material is 2.5 eV and an Ea value of CBP that mainly transports electrons in the light-emitting layer is 2.7 eV, a barrier is formed to inhibit moving of electrons, whereby a blocking property is exhibited.

The thickness of the intermediate layer 1 was 15 nm.

Unit light-emitting layer 2: a light-emitting layer having a composition the same as that of unit light-emitting layer 1 was vapor deposited at a film thickness of 20 nm.

Intermediate layer 2: intermediate layer 2 has a composition the same as that of intermediate layer 1 and a film thickness of 15 nm.

Unit light-emitting layer 3: a light-emitting layer having a composition the same as that of unit light-emitting layer 1 was vapor deposited at a film thickness of 20 nm.

### (Preparation of Comparative Organic EL Element No. 2)

Comparative organic EL element No. 2 was prepared similarly to a comparative organic EL element No. 1, except that, in the light emitting layer, an electron transporting material C was used instead of CBP, and Ir(btp)₂(acac) was used instead of Ir(ppy)₃ of the light emitting layer were used.

### (Preparation of Comparative Organic EL Element No. 2A)

Comparative organic EL element No. 2A was prepared similarly to the comparative organic EL element No. 1A, except that in the light-emitting layer an electron transporting material A was used instead of CBP, and Ir(btp)₂(acac) was used instead of Ir(ppy)₃.

### (Preparation of Organic EL Element No. 1 of the Invention)

In the process of preparing the comparative organic EL element No. 1, the light emitting layer was divided into three unit light emitting layers as shown below, and between the respective unit light emitting layers, intermediate layers 1 and 2 as shown below were disposed as electric-charge blocking layers shown below. Sequentially from a hole transport layer, a unit light emitting layer 1/an intermediate layer 1/a unit light emitting layer 2/an intermediate layer 2/a unit light emitting layer 3 were disposed.

Unit light emitting layer 1: a light emitting layer having a composition the same as that of comparative example No. 1 was vapor deposited at a film thickness of 25 nm.

Intermediate Layer 1: <Example of Intermediate Layer Containing Electron Blocking Material>

A hole transporting material C and Ir(ppy)₃ were co-deposited at a volume ratio of 95:5 to form an intermediate layer. The thickness of the intermediate layer 1 was 5 nm.

Unit light emitting layer 2: a light emitting layer having a composition the same as that of comparative example No. 1 was vapor deposited at a film thickness of 25 nm.

Intermediate layer 2: intermediate layer 2 has a composition the same as that of intermediate layer 1 and a film thickness of 10 nm.

Unit light emitting layer 3: a light emitting layer having a composition the same as that of comparative example No. 1 was vapor deposited at a film thickness of 25 nm.

### 2. Result of Performance Evaluation

For the obtained comparative organic EL element No. 1, 1A and the organic EL element No. 1 of the invention, the external quantum efficiency was measured under the same conditions and by the following means. Further, the brightness decaying time defined as the time required for the brightness to reach 80% to the initial brightness as described above, was measured.

### (Measuring Method for External Quantum Efficiency)

For the prepared light emitting element, a DC voltage was applied by using a source measure unit model 2400 manufactured by KEITHLEY Instruments Inc. to the light emitting element to cause it to emit light. The emission spectrum and the amount of light were measured by using a brightness meter SR-3 manufactured by Topcon Corp., and the external quantum efficiency was calculated based on the emission spectrum, the amount of light, and the current during measurement.

As a result, while the external quantum efficiency was 9.8% in the comparative organic EL element No. 1, and 10.4% in the comparative organic EL element No. 1A, the external quantum efficiency was 12.8% in the organic EL element No. 1 of the invention. While the brightness reduction time was 48 hours in the comparative organic EL element No. 1, and 51 hours in the comparative organic EL element No. 1A, the brightness reduction time was 80 hours in the organic EL element No. 1 of the invention. It was a quite unexpected result that high external quantum efficiency and high driving durability were exhibited even though the total thickness for the two intermediate layers and the three unit light emitting layers was equal with the 90 nm thickness for the comparative organic EL element.

### Example 2

### 1. Preparation of Organic EL Element No. 2 of the Invention

In the process preparing the comparative organic electroluminescence element No. 1, the light emitting layer was divided into 4 unit light emitting layers as shown below, and between the respective unit light emitting layers, intermediate layers 11 to 13 described below were disposed. Sequentially, from a hole transport layer, a unit light emitting layer 11/an intermediate layer 11/a unit light emitting layer 12/an intermediate layer 12/a unit light emitting layer 13/an intermediate layer 13/a unit light emitting layer 14 were disposed.

Unit light emitting layers 11 to 14: a composition the same as that of the light emitting layer of comparative organic EL element No. 1 was vapor deposited at the thickness of 15 nm for each layer.

Intermediate Layers 11, 12 and 13: <Example for Including Hole Blocking Material>

An electron transporting material B and Ir(ppy)₃ were co-deposited at a volume ratio of 95:5 to form an intermediate layer.

The thickness of the intermediate layers 11 was 5 nm.

The thickness of the intermediate layers 12 was 10 nm.

The thickness of the intermediate layers 13 was 15 nm.

That is, the light emitting layer has a constitution finely divided into 7 layers in total for including unit light emitting layer 11/intermediate layer 11/unit light emitting layer 12/intermediate layer 12/unit light emitting layer 13/intermediate layer 13/unit light emitting layer 14, having a total thickness of 90 nm, which is identical with the thickness of the light emitting layer of the comparative organic EL element No. 1 in example 1.

### 2. Result of Performance Evaluation

For the obtained organic EL element No. 2 of the invention, the external quantum efficiency and the brightness decaying time were measured in the same manner as in Example 1.

As a result, the external quantum efficiency of the organic EL element No. 2 of the invention showed an extremely high value of 13.2%, and the brightness reduction time showed an extremely high value of 82 hours.

### Example 3

### 1. Preparation of Organic EL Element No. 3

In the process of preparing Example 2, intermediate layers having an electron blocking capacity, each having the following composition, were used as the intermediate layers.

Sequentially, from a hole transport layer, unit light emitting layer 21, intermediate layer 21, unit light emitting layer 22, intermediate layer 22, unit light emitting layer 23, intermediate layer 23 and unit light emitting layer 24 were disposed.

Each of the unit light emitting layers 21 to 24 had the same composition as the light emitting layer in the comparative organic EL element No. 1, and was vapor-deposited to have a thickness of 15 nm.

The intermediate layers 21 to 23 respectively contained hole transport materials A to C together with Ir(ppy)₃, where the hole transport material/Ir(ppy)₃ volumetric ratio was set at 95:5.

Intermediate layer 21: <hole transport material A (Ea: 2.3 eV)>

Intermediate layer 22: <hole transport material B (Ea: 2.4 eV)>

Intermediate layer 23: <hole transport material C (Ea: 2.5 eV)>

Each of the intermediate layers was 10 nm thick.

### 2. Result of Performance Evaluation

For the obtained organic EL element No. 3 of the invention, the external quantum efficiency and the brightness decaying time were measured in the same manner as in Example 1.

As a result, the external quantum efficiency of the organic EL element No. 3 of the invention showed an extremely high value of 13.5%, and the brightness reduction time showed an extremely high value of 85 hours.

### Example 4

### 1. Preparation of Organic EL Element No. 4

In Example 2, intermediate layers having a hole blocking capacity, each having the following composition, were used as the intermediate layers.

Sequentially, from a hole transport layer, unit light emitting layer 31, intermediate layer 31, unit light emitting layer 32, intermediate layer 32, unit light emitting layer 33, intermediate layer 33 and unit light emitting layer 34 were disposed.

Each of the unit light emitting layers 31 to 34 had the same composition as the light emitting layer in the comparative organic EL element No. 1, and was vapor-deposited to have a thickness of 15 nm.

The intermediate layers 31 to 33 respectively contained electron transport materials A to C together with/Ir(ppy)₃, where the hole transport material/Ir(ppy)₃ volumetric ratio was set at 95:5.

Intermediate layer 31: <electron transport material A (Ip: 6.2 ev)>

Intermediate layer 32: <electron transport material B (Ip: 6.4 eV)>

Intermediate layer 33: <electron transport material C (Ip: 6.6 eV)>

Each of the intermediate layers was 10 nm thick.

### 2. Result of Performance Evaluation

For the obtained organic EL element No. 4 of the invention, the external quantum efficiency and the brightness decaying time were measured in the same manner as in Example 1.

As a result, the external quantum efficiency of the organic EL element No. 4 of the invention showed an extremely high value of 13.4%, and the brightness reduction time showed an extremely high value of 84 hours.

### Example 5

### 1. Preparation of Organic EL Element No. 5

In the process preparing Example 2, intermediate layers having an electron blocking capacity, each having the following composition, were used as the intermediate layers.

Sequentially, from a hole transport layer, unit light emitting layer 41, intermediate layer 41, unit light emitting layer 42, intermediate layer 42, unit light emitting layer 43, intermediate layer 43 and unit light emitting layer 44 were disposed.

Each of the unit light emitting layers 41 to 44 had the same composition as the light emitting layer in the comparative organic EL element No. 1, and was vapor-deposited to have a thickness of 15 nm.

Intermediate layer 41: hole transport material C:CBP:Ir(ppy)₃=50:45:5 by volumetric ratio.

Intermediate layer 42: hole transport material C:CBP:Ir(ppy)₃=30:65:5 by volumetric ratio.

Intermediate layer 43: hole transport material C:CBP:Ir(ppy)₃=10:85:5 by volumetric ratio.

Each of the intermediate layers was 10 nm thick.

### 2. Result of Performance Evaluation

For the obtained organic EL element No. 5 of the invention, the external quantum efficiency and the brightness decaying time were measured in the same manner as in Example 1.

As a result, the external quantum efficiency of the organic EL element No. 5 of the invention showed an extremely high value of 13.6%, and the brightness reduction time showed an extremely high value of 87 hours.

### Example 6

### 1. Preparation of Organic EL Element No. 6

In the process preparing Example 2, intermediate layers having hole blocking capacity, each having the following composition, were used as the intermediate layers.

Sequentially, from a hole transport layer, unit light emitting layer 51, intermediate layer 51, unit light emitting layer 52, intermediate layer 52, unit light emitting layer 53, intermediate layer 53 and unit light emitting layer 54 were disposed.

Each of the unit light emitting layers 51 to 54 had the same composition as the light emitting layer in the comparative organic EL element No. 1, and was vapor-deposited to have a thickness of 15 nm.

Intermediate layer 51: hole transport material B:CBP:Ir(ppy)₃=10:85:5 by volume ratio

Intermediate layer 52: hole transport material B:CBP:Ir(ppy)₃=30:65:5 by volume ratio

Intermediate layer 53: hole transport material B:CBP:Ir(ppy)₃=50:45:5 by volume ratio

Each of the intermediate layers was 10 nm thick.

### 2. Result of Performance Evaluation

For the obtained organic EL element No. 6 of the invention, the external quantum efficiency and the brightness decaying time were measured in the same manner as in Example 1.

As a result, the external quantum efficiency of the organic EL element No. 6 of the invention showed an extremely high value of 13.7%, and the brightness reduction time showed an extremely high value of 88 hours.

### Example 7

### 1. Preparation of Organic EL Element No. 7

In the process preparing Example 2, the intermediate layers, each containing a material of different electron mobility from each other, were used. Each composition is described below.

Sequentially, form a hole transport layer, unit light emitting layer 61, intermediate layer 61, unit light emitting layer 62, intermediate layer 62, unit light emitting layer 63, intermediate layer 63 and unit light emitting layer 64 were disposed.

Each of the unit light emitting layers 61 to 64 had the same composition as the light emitting layer in the comparative organic EL element No. 2, and was vapor-deposited to have a thickness of 15 nm.

The intermediate layers 61 to 63 respectively contained Balq, CBP and the electron transport material B together with Ir(btp)₂(acac), where the volumetric ratio of Balq, CBP or electron transport material B to Ir(btp)₂(acac) was set at 95:5.

Intermediate layer 61: <Balq (electron mobility: 2.5×10⁻⁵ cm²V⁻¹·s⁻¹)>

Intermediate layer 62: <CBP (electron mobility: 6.0×10⁻⁴ cm²V⁻¹·s⁻¹)>

Intermediate layer 63: <electron transport material B (electron mobility: 9.0×10⁻⁴ cm²V⁻¹·s⁻¹)>

The electron mobility data shown above are values under an electric field of 10⁶ V/cm².

Each of the intermediate layers was 10 nm thick.

### 2. Result of Performance Evaluation

For the obtained organic EL element No. 7 of the invention and comparative organic EL element No. 2, 2A, the external quantum efficiency and the brightness decaying time were measured in the same manner as in Example 1.

As a result, while the external quantum efficiency was 4.8% in the comparative organic EL element No. 2, 5.2% in the comparative organic EL element No. 2A, the external quantum efficiency of the organic EL element No. 7 of the invention showed an extremely high value of 7.4%. While the brightness reduction time was 65 hours in the comparative organic EL element No. 2, and 72 hours in the comparative organic EL element No. 2A, the brightness reduction time was 93 hours in the organic EL element No. 7 of the invention, that is extremely improved driving durability.

### Example 8

### 1. Preparation of Organic EL Element No. 8

In the process preparing Example 2, intermediate layers, each containing a material of different hole mobility from each other, were used. Each composition is described below.

Sequentially, from a hole transport layer, unit light emitting layer 71, intermediate layer 71, unit light emitting layer 72, intermediate layer 72, and unit light emitting layer 73 were disposed.

Each of the unit light emitting layers 71 to 73 had the same composition as the light emitting layer in the comparative organic EL element No. 1, and was vapor-deposited to have a thickness of 20 nm.

The intermediate layers 71 to 72 respectively contained the hole transport material A, hole transport material C (mCP) and hole transport material D together with Ir(Ppy)₃, where the volumetric ratio of the hole transport material A, hole transport material C (mCP) or hole transport material D to Ir(ppy)₃ was set at 95:5.

Intermediate layer 71: <hole transport material C (hole mobility: 1.7×10⁻⁴ cm²V⁻¹·s⁻¹)>

Intermediate layer 72: <hole transport material D (hole mobility: 6.5×10⁻⁵ cm²V⁻¹·s⁻¹)>

The hole mobility shown above are values under an electric field of 10⁶ V/cm².

Each of the intermediate layers was 15 nm thick.

### 2. Result of Performance Evaluation

For the obtained organic EL element No. 8 of the invention and comparative organic EL element No. 1, the external quantum efficiency and the brightness decaying time were measured in the same manner as in Example 1.

As a result, while the external quantum efficiency was 9.8% in the comparative organic EL element No. 1, and 10.4% in the comparative organic EL element No. 1A, the external quantum efficiency of the organic EL element No. 8 of the invention showed an extremely high value of 12.1%. While the brightness reduction time was 48 hours in the comparative organic EL element No. 1, and 51 hours in the comparative organic EL element No. 1A, the brightness reduction time was 81 hours in the organic EL element No. 8 of the invention, that is extremely improved driving durability.

Structures of the compounds used in the above-described organic EL elements are shown below.

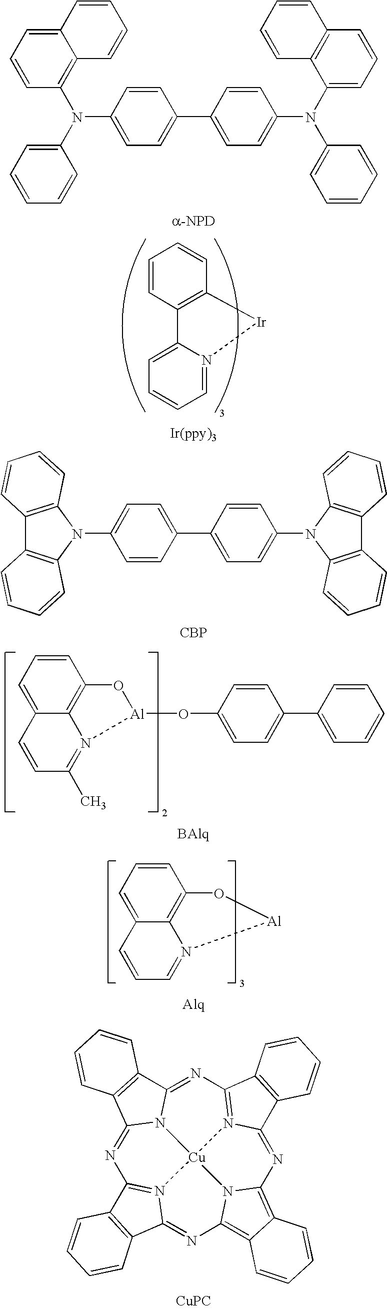

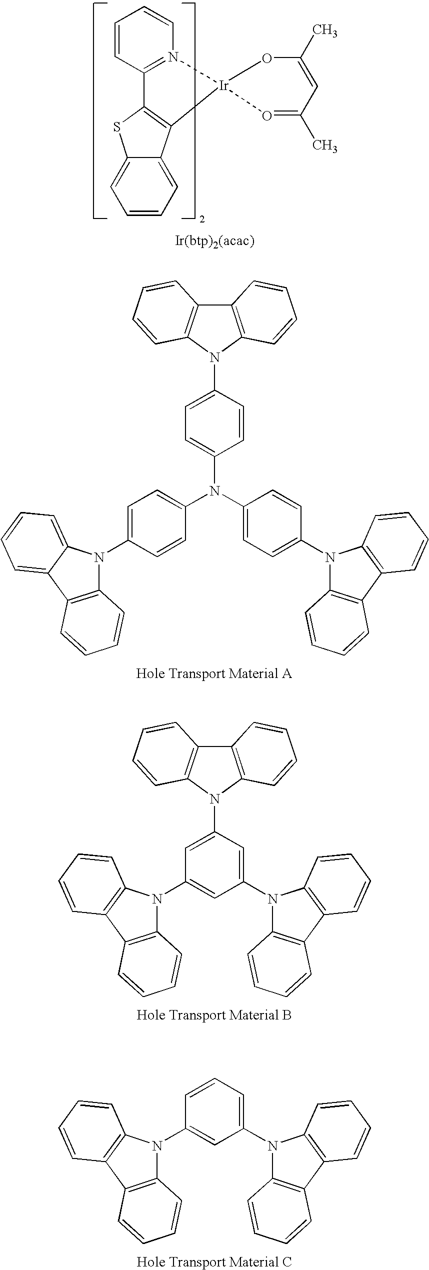

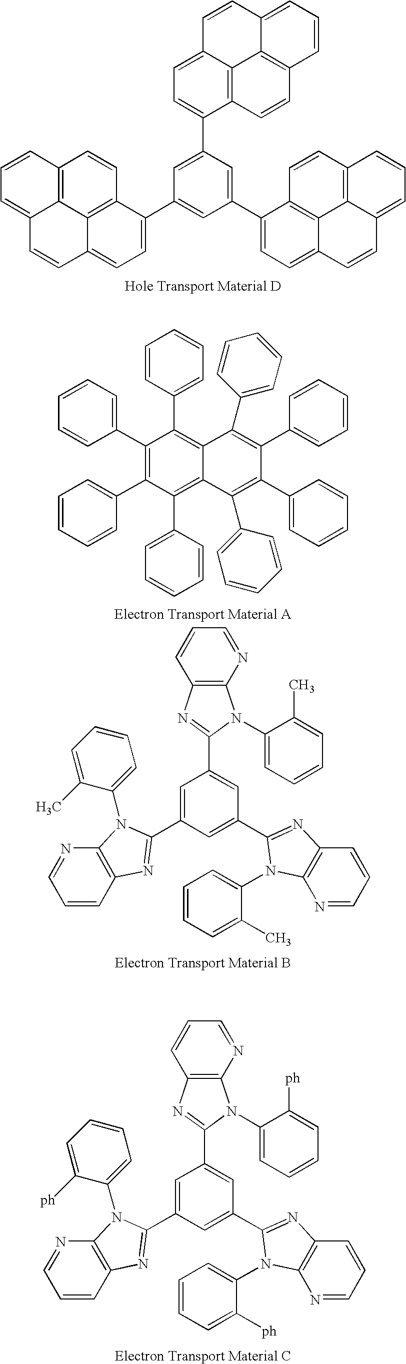

### DESCRIPTION OF REFERENCE NUMBERS USED IN THE DRAWINGS

1: anode, 2: hole injection layer, 3: hole transport layer, 4: light-emitting layer, 4a, 4b, 4c, 4d: unit light-emitting layers, 5: electron transport layer, 6: electron injection layer, 7: cathode, 8: intermediate layer, 8a, 8b, 8c: intermediate layers dividing light-emitting layer.

What is claimed is:

1. An organic electroluminescence element having at least a light emitting layer between a pair of electrodes, wherein the light emitting layer is segmented into at least 3 unit light emitting layers in the thickness direction thereof, and at least 2 intermediate layers each containing an electron blocking material are disposed between the adjacent unit light emitting layers, wherein an electron blocking capacity of the intermediate layer is highest in the intermediate layer disposed closer to the anode, and lowest in the intermediate layer disposed closer to the cathode.

2. An organic electroluminescence element having at least a light emitting layer between a pair of electrodes, wherein the light emitting layer is segmented into at least 3 unit light emitting layers in the thickness direction thereof, and at least 2 intermediate layers each containing a hole blocking material are disposed between the adjacent unit light emitting layers, wherein a hole blocking capacity of the intermediate layer is lowest in the intermediate layer disposed closer to the anode, and highest in the intermediate layer disposed closer to the cathode.

3. The organic electroluminescence element according to claim 1, wherein an electron affinity (Ea) of the electron blocking material is lowest in the intermediate layer disposed closer to the anode, and highest in the intermediate layer disposed closer to the cathode.

4. The organic electroluminescence element according to claim 2, wherein an ionization potential (Ip) of the hole blocking material is lowest in the intermediate layer disposed closer to the anode, and highest in the intermediate layer disposed closer to the cathode.

5. The organic electroluminescence element according to claim 1, wherein a concentration of the electron blocking material in the intermediate layer is highest in the intermediate layer disposed closer to the anode, and lowest in the intermediate layer disposed closer to the cathode.

6. The organic electroluminescence element according to claim 2, wherein a concentration of the hole blocking material in the intermediate layer is lowest in the intermediate layer disposed closer to the anode, and highest in the intermediate layer disposed closer to the cathode.

7. The organic electroluminescence element according to claim 1, wherein an electron mobility of the intermediate layer is lowest in the intermediate layer disposed closer to the anode, and highest in the intermediate layer disposed closer to the cathode.

8. The organic electroluminescence element according to claim 2, wherein a hole mobility of the intermediate layer is highest in the intermediate layer disposed closer to the anode, and lowest in the intermediate layer disposed closer to the cathode.

9. The organic electroluminescence element according to claim 1, wherein a thickness of the intermediate layer is thickest in the intermediate layer disposed closer to the anode, and thinnest in the intermediate layer disposed closer to the cathode.

10. The organic electroluminescence element according to claim 2, wherein a thickness of the intermediate layer is thinnest in the intermediate layer disposed closer to the anode, and thickest in the intermediate layer disposed closer to the cathode.

11. The organic electroluminescence element according to claim 1, wherein the light emitting layer contains a phosphorescent material as a light emitting material.

12. The organic electroluminescence element according to claim 2, wherein the light emitting layer contains a phosphorescent material as a light emitting material.

13. The organic electroluminescence element according to claim 1, wherein the intermediate layer contains a light emitting material.

14. The organic electroluminescence element according to claim 2, wherein the intermediate layer contains a light emitting material.

15. The organic electroluminescence element according to claim 13, wherein the light emitting material contained in the intermediate layer is a phosphorescent material.

16. The organic electroluminescence element according to claim 14, wherein the light emitting material contained in the intermediate layer is a phosphorescent material.
